(19) United States
(12) Patent Application Publication
(10) Pub. No.: US 2011/0178745 A1
(43) Pub. Date: Jul. 21, 2011

(54) ELECTRONIC DEVICES, REMAINING BATTERY ENERGY LEVEL DISPLAYING METHOD, AND OPERABLE TIME DISPLAYING METHOD

(75) Inventor: Kazuhide Kobayashi, Kanagawa-ken (JP)

(73) Assignee: VICTOR COMPANY OF JAPAN, LIMITED, Yokohama-shi, Kanagawa (JP)

(21) Appl. No.: 13/120,097

(22) PCT Filed: Sep. 22, 2008
(86) PCT No.: PCT/JP2008/067059

§ 371 Date: Mar. 21, 2011

(51) Int. Cl. G01R 31/36; G06F 19/00

(52) U.S. Cl. 702/63

(57) ABSTRACT

Provision of electronic devices adapted to display a remaining energy level of a battery in service in combination with remaining energy levels of batteries out of service, or display an operable time by a remaining energy level of a battery in service in combination with an operable time by remaining energy levels of batteries out of service, and a remaining battery energy level displaying method and an operable time displaying method applicable thereto.

An electronic device 1 operable with battery-derived power includes an ID reader 2 for reading a battery ID of a battery in service attached to the electronic device 1, a remaining battery energy level calculator 4 for calculating a remaining energy level of the battery in service 20, a remaining battery energy level memory 5 for storing therein remaining energy levels of batteries subjected to selective attachment to the electronic device 1, respectively associated with battery IDs thereof, a screen display 7, and a display controller for implementing a control to display on the screen display 7 a first set of information on remaining energy level representative of a remaining energy level of the battery in service 20, and a second set of information on remaining energy level representative of remaining energy levels of batteries out of service else than the battery in service having remaining energy levels thereof stored in the remaining battery energy level memory 5.

### FIELD OF ART

The present invention relates to electronic devices to be driven by batteries, and a remaining battery energy level displaying method and an operable time displaying method applicable thereto.

### BACKGROUND ART

There have been electronic devices each configured for batteries to be attachable thereto, and adapted to display a remaining energy level of a battery in service, but inadaptable for any display of remaining energy level of all the batteries, and for any grasp to be made of a total of remaining energy levels of all the batteries by the user.

To this point, Patent Literature 1 has proposed a technique of using a table listing correspondences between measured voltages and remaining energy levels of batteries, and a calculator for calculating a mean of individually measured voltages of respective batteries, to determine remaining energy levels of the batteries, working on the results to determine a total remaining energy level of a set of batteries, to display on a screen.

Further, Patent Literature 2 has disclosed a technique of using a battery in a main frame of camera or a battery in a battery grip as an auxiliary power supply, whichever is selective in accordance with consumption, displaying the course of battery consumption of an entirety being combination of the two batteries.
Patent Literature 1: Japanese Patent Application Laying-Open Publication No: 5-99998
Patent Literature 2: Japanese Patent Application Laying-Open Publication No: 2006-3501

### SUMMARY OF INVENTION

### Problem to be Solved

For portable electronic devices such as video cameras and digital cameras, the device size as well as the weight significantly affects user convenience and portability, so batteries simultaneously attached would penalize the user. For portable electronic devices, it therefore is common to have a single battery attached to a device, leaving other batteries as they are detached from the device for the user to carry for replacement.

In such the case, the device displays as a remaining battery energy level no more than a remaining energy level of the battery in service attached to the device, and is unable to add thereto remaining energy levels of the other batteries left detached from the device, to display the result. Thus, users have been unable to grasp, among others, a sum of remaining energy levels including such as those of batteries being carried for replacement besides a battery in service, or an interval of time for the device to be operable with the remaining energy level.

The Patent Literatures 1 and 2 described were each respectively such one as being adapted to display a remaining energy level of a battery attached to a device, failing to display remaining energy levels of batteries left detached from the device.

The present invention has been devised in view of the foregoing, and has as its object provision of electronic devices adapted to display a remaining energy level of a battery in service in combination with remaining energy levels of batteries out of service, or display an operable time by a remaining energy level of a battery in service in combination with an operable time by remaining energy levels of batteries out of service, and provision of a remaining battery energy level displaying method and an operable time displaying method applicable thereto.

### Solution to Problem

According to an aspect of the present invention, there is an electronic device operable with battery-derived power, the electronic device comprising an ID reader configured to read a battery ID of a battery in service attached to the electronic device, a remaining battery energy level calculator configured to calculate a remaining energy level of the battery in service, a remaining battery energy level memory configured to store therein remaining energy levels of batteries subjected to selective attachment to the electronic device, respectively associated with battery IDs thereof, a screen display, and a display controller configured for control to display on the screen display a first set of information on remaining energy level representative of the remaining energy level of the battery in service, and a second set of information on remaining energy level representative of remaining energy levels of batteries out of service else than the battery in service having remaining energy levels thereof stored in the remaining battery energy level memory.

According to another aspect of the present invention, there is an electronic device operable with battery-derived power, the electronic device comprising an ID reader configured to read a battery ID of a battery in service attached to the electronic device, a remaining battery energy level calculator configured to calculate a remaining energy level of the battery in service, a remaining battery energy level memory configured to store therein remaining energy levels of batteries subjected to selective attachment to the electronic device, respectively associated with battery IDs thereof, an operable time calculator configured to work on bases of respective remaining energy levels of the batteries, to calculate operable times for the electronic device to be operable by the batteries, respectively, a screen display, and a display controller configured for control to display on the screen display a first set of information on operable time representative of an operable time by the battery in service, and a second set of information on operable time representative of operable times by batteries out of service else than the battery in service having remaining energy levels thereof stored in the remaining battery energy level memory.

According to another aspect of the present invention, there is a remaining battery energy level displaying method comprising reading a battery ID of a battery in service attached to an electronic device, calculating a remaining energy level of the battery in service, having remaining energy levels of batteries subjected to selective attachment to the electronic device, respectively associated with battery IDs thereof, stored in a remaining battery energy level memory, and displaying on a screen display a first set of information on remaining energy level representative of the remaining energy level of the battery in service, and a second set of information on remaining energy level representative of remaining energy levels of batteries out of service else than the battery in service having remaining energy levels thereof stored in the remaining battery energy level memory.

According to another aspect of the present invention, there is an operable time displaying method comprising reading a battery ID of a battery in service attached to an electronic device, calculating a remaining energy level of the battery in service, having remaining energy levels of batteries subjected to selective attachment to the electronic device, respectively associated with battery IDs thereof, stored in a remaining battery energy level memory, working on bases of respective remaining energy levels of the batteries, to calculate operable times for the electronic device to be operable by the batteries, respectively, and displaying on a screen display a first set of information on operable time representative of an operable time by the battery in service, and a second set of information on operable time representative of operable times by batteries out of service else than the battery in service having remaining energy levels thereof stored in the remaining battery energy level memory.

### Advantageous Effects of Invention

According to the present invention, it is possible to display a remaining energy level of a battery in service in combination with remaining energy levels of batteries out of service. It also is possible to display an operable time by a remaining energy level of a battery in service in combination with an operable time by remaining energy levels of batteries out of service

### BRIEF DESCRIPTION OF DRAWINGS

FIG. 1 is a block diagram of configuration of an electronic device according to a first embodiment of the present invention.

FIG. 2A is a flowchart of actions of the electronic device in the first embodiment.

FIG. 2B is a flowchart of actions of the electronic device in the first embodiment.

FIG. 3 is a flowchart of procedure for a process of correcting stored remaining energy levels of batteries in the first embodiment.

FIG. 4 is a flowchart of procedure for a process of displaying remaining energy levels in the first embodiment.

FIG. 5 is an illustration of an example of remaining energy level display screen in the first embodiment.

FIG. 6 is an illustration of an example of total capacity and remaining energy level display graphic in FIG. 5.

FIG. 7 is an illustration of an example of individual capacity and remaining energy level display graphic in FIG. 5.

FIG. 8 is an illustration of another example of remaining energy level display screen in the first embodiment.

FIG. 9 is an illustration of still another example of remaining energy level display screen in the first embodiment.

FIG. 10 is an illustration of an example of remaining energy level display screen displaying a message prompting a selection by user to or not to store a remaining energy level of a battery in service.

FIG. 11 is an illustration of an example of remaining energy level display screen displaying a message for deletion of a remaining energy level stored in a remaining battery energy level memory.

FIG. 12 is an illustration of an example of battery ID indication on a battery.

FIG. 13 is a block diagram of configuration of an electronic device according to a second embodiment of the present invention.

FIG. 14A is a flowchart of actions of the electronic device in the second embodiment.

FIG. 14B is a flowchart of actions of the electronic device in the second embodiment.

FIG. 15 is a flowchart of procedure for a process of displaying operable times in the second embodiment.

FIG. 16 is an illustration of an example of operable time display screen in the second embodiment.

FIG. 17 is an illustration of a total operable time display graphic in FIG. 16.

FIG. 18 is an illustration of an individual operable time display graphic in FIG. 16.

### PREFERRED EMBODIMENTS OF THE INVENTION

There will be described preferred embodiments of the present invention, with reference to the drawings.

### First Embodiment

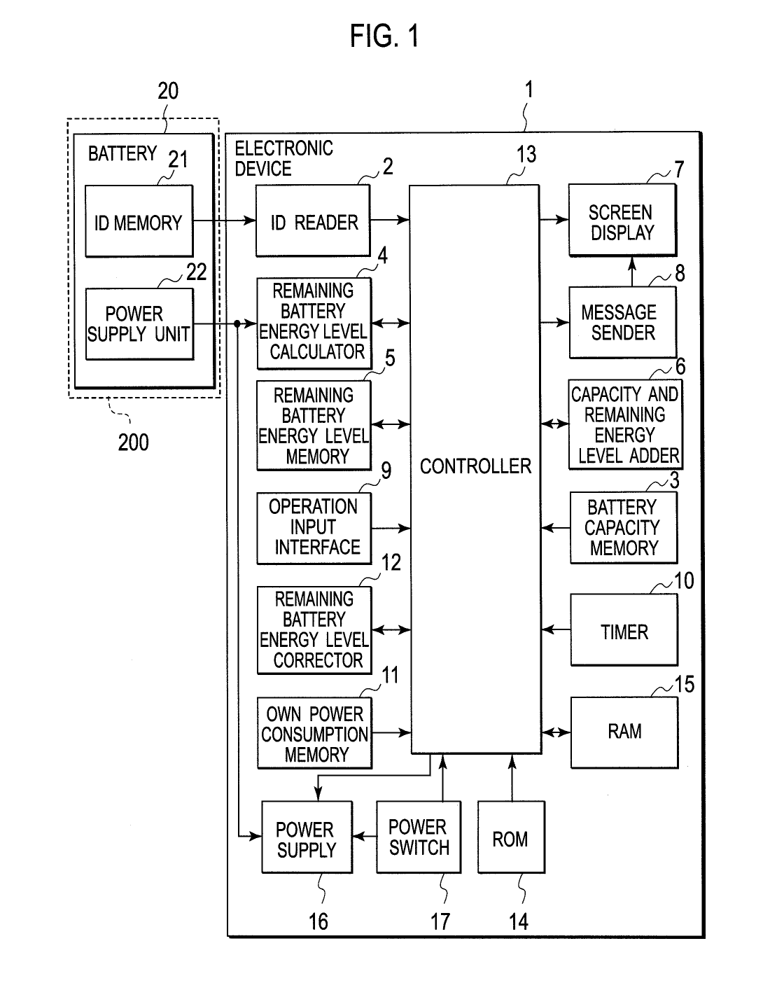

FIG. 1 is a block diagram of configuration of an electronic device according to a first embodiment of the present invention. As shown in FIG. 1, according to the first embodiment, there is an electronic device 1 including an ID reader 2, a battery capacity memory 3, a remaining battery energy level calculator 4, a remaining battery energy level memory 5, a capacity and remaining energy level adder 6, a screen display 7, a message sender 8, an operation input interface 9, a timer 10, an own power consumption memory 11, a remaining battery energy level corrector 12, a controller 13, a ROM (Read Only Memory) 14, a RAM (Random Access Memory) 15, a power supply 16, and a power switch 17.

The electronic device 1 is configured for batteries 20 to be attachable thereto, and is drivable by power derived from a battery 20. More specifically, the electronic device 1 includes a battery holder 200 configured for attachment of a battery 20. The battery holder 200 has a battery 20 attached thereto. The battery holder 200 has terminals (non-depicted) as necessary for connections to a battery 20. The battery holder 200 may well be configured to have one or more batteries 20 attached thereto. There are batteries 20 subjected to selective attachment to the battery holder 200.

Each battery 20 includes an ID memory 21 for holding a unique battery ID of the battery, and a power supply unit 22 for supplying power to the electronic device 1. It is preferable for the battery ID to include information on battery type representative of a type of the battery. For instance, there may be a battery ID itself including information on battery type, such as a battery ID representing a battery for 30 minutes service if the initial is “1”, a battery for 60 minutes service if it is “2”, or a battery for 90 minutes service if it is “3”. Or, the electronic device 1 may have pieces of information indicating battery IDs from some number to some number representing batteries for 30 minutes service, battery IDs from some number to some number representing batteries for 60 minutes service, and battery IDs from some number to some number representing batteries for 90 minutes service.

The ID reader 2 is configured to read a battery ID from an ID memory 21 of a battery in service attached to the electronic device 1.

The battery capacity memory 3 is configured to have a set of capacities of batteries of those types applicable to the electronic device 1, associated with pieces of information on type of battery, stored therein in advance.

The remaining battery energy level calculator 4 is configured to calculate a remaining energy level of a battery 20. For the calculation of remaining energy level, there may be measurement of a voltage across terminals of the battery 20, for instance. More specifically, there may be use of a measurement of voltage across terminals, to detect how much the remaining energy level of the battery 20 is reduced. For any battery of each of the above-noted types, the remaining battery energy level calculator 4 is adapted to calculate a remaining energy level based on combination of a measurement of voltage across terminals and a capacity in the battery capacity memory 3.

As a battery 20 to be available, there may be such one that is adapted to supply the electronic device 1 with a set of data on capacity and remaining energy level of the battery. For such the type of battery employed as a battery 20, there may be an implementation excluding battery capacity memory 3, and including a remaining battery energy level calculator 4 configured to work on a data on remaining energy level supplied from the battery 20, to calculate a remaining energy level of the battery 20.

The remaining battery energy level memory 5 is configured to store therein a remaining energy level of a battery 20 calculated by the remaining battery energy level calculator 4, as it is associated with combination of a battery ID of the battery 20, and a remaining energy level storage time that is the time the remaining energy level is stored. The remaining battery energy level memory 5 is configured to have a set of remaining energy levels of those batteries having been attached to the electronic device 1 (the battery holder 200) and given user's instructions for storage of remaining energy level of battery as will be described later on, as they are associated with the batteries' battery IDs and remaining energy level storage times thereof, stored therein. Such being the case, it is preferable to have combination of a remaining energy level and a remaining energy level storage time, associated with a battery ID, and stored. For a battery, the remaining energy level is decreased with lapse of time, and the storage of remaining energy level storage time permits a correction to be made of a stored remaining energy level, as will be described later on. There may also be an implementation excluding the function of correcting a stored remaining energy level of battery, and adapted for storage of a remaining energy level associated with a battery ID.

The capacity and remaining energy level adder 6 is configured to calculate a total battery capacity that is a sum of a capacity of a battery in service 20 and capacities of stored batteries else than the battery in service 20 among those stored batteries having remaining energy levels thereof stored in the remaining battery energy level memory 5, and calculate a total remaining battery energy level that is a sum of a remaining energy level of the battery in service 20 and remaining energy levels of the stored batteries else than the battery in service 20.

The screen display 7 is configured to display a later-described total capacity and remaining energy level display graphic as well as individual capacity and remaining energy level display graphics representative of capacities and remaining energy levels of batteries, and various messages or the like.

The message sender 8 is configured to have a variety of messages to user, sent to the screen display 7, and displayed thereon.

The operation input interface 9 is configured as a part for user to make an input of operation to the electronic device 1, and works to output to the controller 13 an operation signal according to user's operation.

The timer 10 is configured to count a time. The timer 10 to be operable even after detachment of battery 20 is adapted to operate with power supplied from some power source (non-depicted) such as a battery incorporated in the electronic device 1, else than a battery 20.

The own power consumption memory 11 is configured to have respective own power consumptions of batteries of types applicable to the electronic device 1, associated with pieces of information on type of battery, stored therein in advance.

The remaining battery energy level corrector 12 is configured to: calculate a remaining energy level correction value based on combination of an own power consumption per unit time obtained from the own power consumption memory 11 and a difference between a current time and a remaining energy level storage time of a stored battery that is that battery which has a remaining energy level thereof, associated with a battery ID and the remaining energy level storage time, stored in the remaining battery energy level memory 5; and use the remaining energy level correction value to correct a remaining energy level of the stored battery.

The controller 13 is configured to implement program-compliant processes to control actions of an entirety of electronic device 1. For the controller 13, control items enumerated include reading a battery ID at the ID reader 2, reading a capacity from the battery capacity memory 3, controlling the remaining battery energy level calculator 4, storing remaining energy levels and the like in the remaining battery energy level memory 5, controlling the capacity and remaining energy level adder 6, controlling display on the screen display 7, controlling the message sender 8, responding to an operation input through the operation input interface 9, acquiring temporal information from the timer 10, reading an own power consumption from the own power consumption memory 11, controlling the remaining battery energy level corrector 12, effecting power supply on-off control in response to the power switch 17, reading data of the ROM 14, and executing various operational processes.

The controller 13 is configured to function as a display controller for control to display on the screen display 7 a first set of information on remaining energy level representative of a remaining energy level of a battery in service 20, and a second set of information on remaining energy level representative of remaining energy levels of batteries out of service else than the battery in service having remaining energy levels thereof stored in the remaining battery energy level memory 5.

The controller 13 is configured to function as a remaining energy level update controller to have the remaining battery energy level calculator 4 calculate, every prescribed time T, a remaining energy level of a battery in service 20 out of stored batteries, thereby updating a remaining energy level and a remaining energy level storage time of the battery in service 20 stored in the remaining battery energy level memory 5.

The controller 13 is configured to function as a remaining energy level storage controller to work for attachment to the electronic device 1 of a new battery having no remaining energy level stored in the remaining battery energy level memory 5, followed by an instruction signal input for storage of remaining energy level of the new battery, to have a remaining energy level of the new battery, associated with a battery ID and a remaining energy level storage time of the battery, stored in the remaining battery energy level memory 5.

The controller 13 is configured to function as a remaining energy level deletion controller to delete, from the remaining battery energy level memory 5, a remaining energy level of a battery instructed by user's operation, and combination of a battery ID and a remaining energy level storage time associated with the remaining energy level.

The ROM 14 is adapted to store therein programs for actions of the controller 13, predetermined values C min of remaining energy levels, prescribed times T, and the like, as will be described later on.

The RAM 15 is adapted for, among others, storage of temporary data, and use as a working area for the controller 13 in operation.

The power supply 16 is configured to receive power from the power supply unit 22 of a battery 20, and supply the electronic device 1 with power to drive.

The power switch 17 is a component adapted for operations by user to power the electronic device 1 on and off, and configured to give a command for supply of power to the power supply 16 in response to an operation by user.

Description is now made of actions of the electronic device 1 according to the first embodiment.

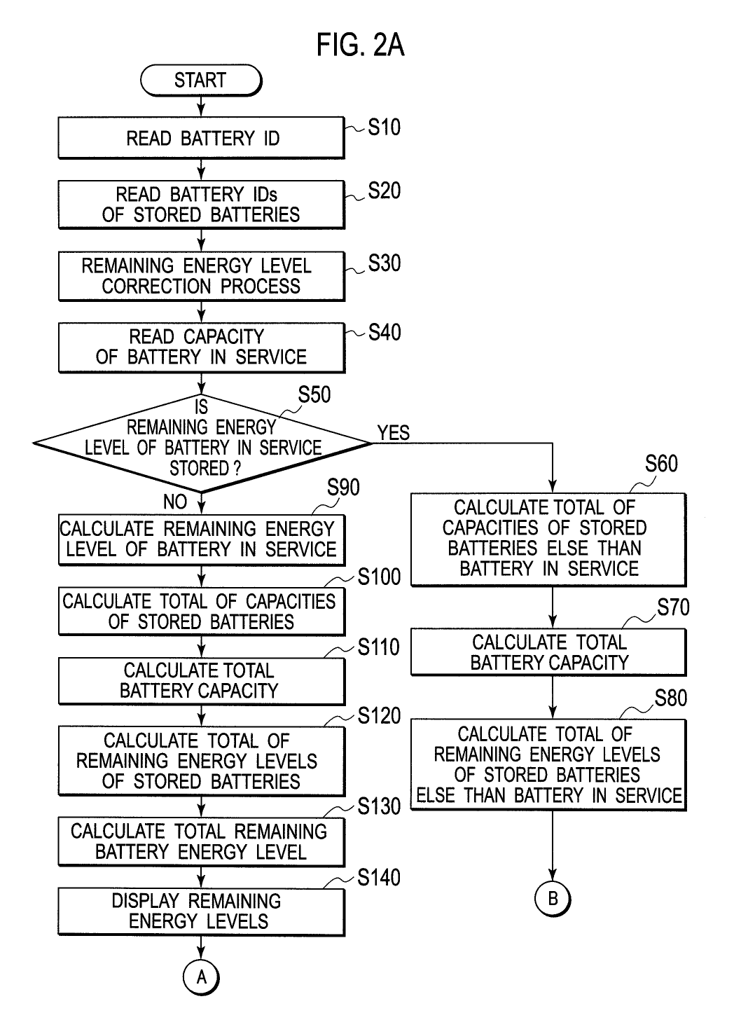

FIG. 2A and FIG. 2B show flowcharts of actions of the electronic device 1. First, in FIG. 2A, at a step S10, the ID reader 2 reads a battery ID stored in the ID memory 21 of a battery in service 20 attached to the electronic device 1, and outputs it to the controller 13.

Subsequently, at a step S20, the controller 13 read battery IDs of all stored batteries that have remaining energy levels thereof, associated with battery IDs and remaining energy level storage times, stored in the remaining battery energy level memory 5.

Subsequently, at a step S30, the controller 13 implements a remaining energy level correction process to correct a remaining energy level of a respective stored battery stored in the remaining battery energy level memory 5. The remaining energy level correction process follows a later-described procedure.

Subsequently, at a step S40, the controller 13 works on the basis of a piece of information on type of battery contained in the battery ID of the battery in service 20, to read a capacity ‘CA’ of the battery in service 20 from the battery capacity memory 3.

Subsequently, at a step S50, the controller 13 works on the basis of battery ID of the battery in service 20, to determine whether or not the battery in service 20 has a remaining energy level thereof stored in the remaining battery energy level memory 5. If it is stored (YES at the step S50), the flow goes to a step S60, but unless it is stored (NO at the step S50), the flow goes to a step S90.

At the step S60, the controller 13 reads from the battery capacity memory 3 capacities of all stored batteries else than the battery in service 20, and works to have the capacity and remaining energy level adder 6 calculate a total ‘CA mem’ of read capacities.

There has been determined a combination of ‘CA’ as a capacity of the battery in service 20 and ‘CA mem’ as a total of capacities of all stored batteries else than the battery in service 20, which can be added to each other to provide a capacity of a set of all applicable batteries, so at a step S70, the controller 13 works to have the capacity and remaining energy level adder 6 calculate a total battery capacity ‘CA all’ as a sum of ‘CA’ and ‘CA mem’.

Subsequently, at a step S80, the controller 13 reads from the remaining battery energy level memory 5 remaining energy levels of all stored batteries else than the battery in service 20, and works to have the capacity and remaining energy level adder 6 calculate a total ‘CR mem’ of read remaining energy levels. Afterward, the flow goes to a step S220 in FIG. 2B.

In FIG. 2A, unless the battery in service 20 has a remaining energy level thereof stored in the remaining battery energy level memory 5 (NO at the step S50), at the step S90 the controller 13 works to have the remaining battery energy level calculator 4 calculate a remaining energy level ‘CR’ of the battery in service 20.

Subsequently, at a step S100, the controller 13 works to have the capacity and remaining energy level adder 6 calculate a total ‘CA mem’ of capacities of all stored batteries having remaining energy levels thereof stored in the remaining battery energy level memory 5, and at a step S110, the controller 13 works to have the capacity and remaining energy level adder 6 calculate a total battery capacity ‘CA all’ as a sum of ‘CV’ and ‘CA mem’.

Subsequently, at a step S120, the controller 13 reads from the remaining battery energy level memory 5 remaining energy levels of all stored batteries, and works to have the capacity and remaining energy level adder 6 calculate a total ‘CR mem’ of read remaining energy levels, and at a step S130, the controller 13 works to have the capacity and remaining energy level adder 6 calculate a total remaining battery energy level ‘CR all’ as a sum of ‘CR mem’ and the remaining energy level ‘CR’ of the battery in service 20.

Subsequently, at a step S140, the controller 13 employs thus determined capacity ‘CA’ of battery in service 20, remaining energy level ‘CR’ of battery in service 20, total battery capacity ‘CA all’, total remaining energy level ‘CR all’, etc., for driving the screen display 7 to display thereon remaining energy levels of the battery in service 20 and other stored batteries, as well as a sum of them. For the remaining energy levels displayed, the mode of display employed is similar to that in a remaining energy level display process to be described later on.

Subsequently, in FIG. 2B, at a step S150, the controller 13 works to have the message sender 8 send a message prompting a selection by user to or not to store the remaining energy level of the battery currently in service 20 in the remaining battery energy level memory 5, to display on the screen display 7. For display of message, examples will be described later.

Description is now made of why the message is displayed. For users, it is unable to know about a battery how the remaining energy is, till the battery gets attached to the electronic device 1. The battery attached may have little energy remaining. In status with small energy remaining, the battery even if stored will not survive for any more than a short time, so it is sometimes undesirable to make storage of a battery with small energy remaining. In this regard, there should be an option to be available “not to store”. It is noted that the implementation of displaying remaining energy levels at the step S140 has it as an objective to make a user recognize how current remaining energy levels are, in the course of decision to or not to store a remaining energy level of a battery.

Subsequently, at a step S160, the controller 13 determines whether or not the power switch 17 is pressed, and if it is pressed (YES at the step S160), then at a step S170, the controller 13 implements a power off process.

Unless the power switch 17 is pressed (NO at the step S160), at a step S180 the controller 13 determines whether or not the remaining energy level ‘CR’ of the battery currently in service 20 is equal to or higher than a predetermined value ‘C min’ stored in the ROM 14.

If it is equal to or higher than the predetermined value ‘C min’ (YES at the step S180), then the flow goes to a step S190, but if it is lower than the predetermined value ‘C min’ (NO at the step S180), then at the step S170, the controller 13 implements the power off process. This is because of the remaining energy level ‘CR’ of the battery 20 residing in a range lower than the predetermined value ‘C min’, where it is substantially impossible to have the electronic device 1 work, so operation of the electronic device 1 is to be automatically stopped even if the power switch 17 is not pressed.

At the step S190, the controller 13 determines whether or not the message at the step S150 is responded by an operation input to the operation input interface 9. If it is responded by an operation input (YES at the step S190), then the flow goes to a step S200, but unless it is responded by an operation input (NO at the step S190), the flow again goes to the step S160 to repeat subsequent processes.

At the step S200, the controller 13 determines whether or not “store” is selected in accordance with an operation signal from the operation input interface 9. If “store” is selected (YES at the step S200), then the flow goes to a step S210, but if “not store” is selected (NO at the step S200), the flow goes to a step S220.

At the step S210, the controller 13 works to read a current time from the timer 10, and have the remaining energy level ‘CR’ of the battery in service 20, associated with the battery ID and the current time as a remaining energy level storage time, written in the remaining battery energy level memory 5.

Subsequently, at the step S220, the controller 13 implements a remaining energy level display process. The remaining energy level display process follows a later-described procedure.

Description is now made of a process to be implemented to correct remaining energy levels of stored batteries at the step S30 in FIG. 2A.

The battery is subject to, among others, self-discharge power, and power consumption such as by an incorporated protection circuit of the battery, and does consume power, though slightly, even in a state disconnected from circuit loads. There may be a state out of service having lasted for a long time after storage of a remaining energy level in the remaining battery energy level memory 5, there being a difference having developed between an actual remaining energy level and the remaining energy level stored in the remaining battery energy level memory 5, accordingly. As a process of correcting such differences of remaining energy levels, the remaining energy level correction process is described below.

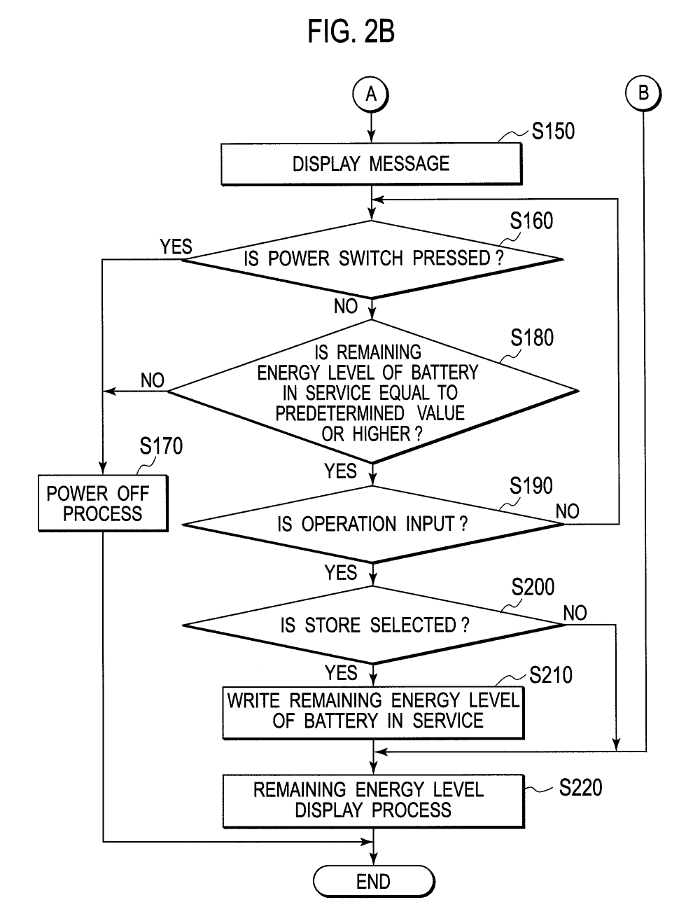

FIG. 3 shows a flowchart of a procedure for the process of correcting remaining energy levels of stored batteries. First, at a step S310, the controller 13 determines whether or not there is any stored battery having a remaining energy level thereof stored in the remaining battery energy level memory 5. If there is any stored battery (YES at the step S310), then the flow goes to a step S320, but if there is no stored battery (NO at the step S310), the process goes to an end.

At the step S320, the controller 13 reads from the remaining battery energy level memory 5 a remaining energy level storage time of a respective stored battery among stored batteries else than a battery currently in service 20, and at a step S330, the controller 13 reads a current time from the timer 10.

Subsequently, at a step S340, the controller 13 calculates a difference of time between the current time and a remaining energy level storage time of the respective stored battery.

Subsequently, at a step S350, the controller 13 works on the basis of a piece of information on type of battery contained in a battery ID of the respective stored battery, to read an own power consumption per unit time of the respective stored battery from the own power consumption memory 11.

Subsequently, at a step S360, the controller 13 controls the remaining battery energy level corrector 12 for multiplying the own power consumption per unit time of the respective stored battery as read from the own power consumption memory 11, by the difference of time calculated at the step S340, to calculate a remaining energy level correction value for correcting a remaining energy level of the respective stored battery.

Subsequently, at a step S360, the controller 13 reads from the remaining battery energy level memory 5 remaining energy levels of stored batteries else than the battery currently in service 20, and at a step S380, the controller 13 controls the remaining battery energy level corrector 12 for use of remaining energy level correction values calculated at the step S360 to correct the read remaining energy levels.

Then, at a step S390, the controller 13 implements a process of writing a corrected remaining energy level of a respective stored battery as calculated by the remaining battery energy level corrector 12, over the remaining battery energy level memory 5, concurrently changing a remaining energy level storage time of the respective stored battery, to a time of the correction.

Description is now made of a process to be implemented to display remaining energy levels at the step S220 in FIG. 2B.

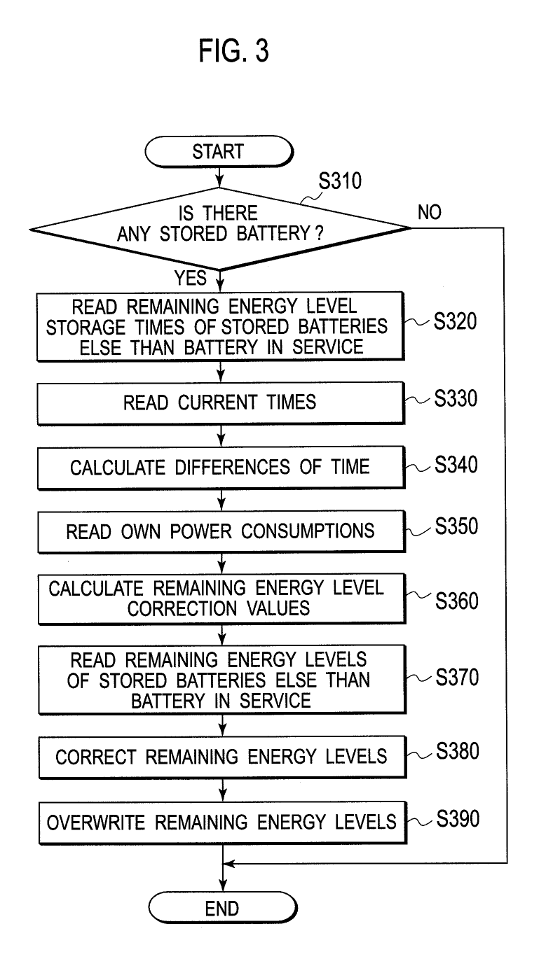

FIG. 4 shows a flowchart of a procedure for the process of displaying remaining energy levels. First, at a step S410, the controller 13 determines whether or not the power switch 17 is pressed, and if it is pressed (YES at the step S410), then at a step S420, the controller 13 implements a power off process.

Unless the power switch 17 is pressed (NO at the step S410), at a step S430 the controller 13 determines whether or not a predetermined time T in the ROM 14 has elapsed after a previous update of remaining energy level. If the predetermined time T has elapsed (YES at the step S420), then the flow goes to a step S440, but unless the predetermined time T has elapsed (NO at the step S420), the flow again goes to the step S410.

At the step S440, the controller 13 works to have the remaining battery energy level calculator 4 calculate a remaining energy level ‘CR’ of a battery currently in service 20.

Subsequently, at a step S450, the controller 13 determines whether or not the remaining energy level ‘CR’ of the battery currently in service 20 as calculated at the step S440 is equal to or higher than a predetermined value ‘C min’ stored in the ROM 14. If the remaining energy level ‘CR’ is equal to or higher than the predetermined value ‘C min’ (YES at the step S450), then the flow goes to a step S460, but if the remaining energy level ‘CR’ is lower than the predetermined value ‘C min’ (NO at the step S450), then at the step S420, the controller 13 implements the power off process.

At the step S460, the controller 13 determines whether or not the battery in service 20 has a remaining energy level thereof stored in the remaining battery energy level memory 5. If it is stored (YES at the step S460), the flow goes to a step S470, but unless it is stored (NO at the step S460), the flow goes to a step S480.

At the step S470, the controller 13 implements a process of writing the remaining energy level ‘CR’ of the battery in service 20, over the remaining battery energy level memory 5 (to update), concurrently changing a remaining energy level storage time to a time of the overwrite.

There is made an overwrite (update) to the remaining battery energy level memory 5, every time of calculation of a remaining energy level of battery in service, the reason why follows.

The electronic device 1 is supplied with power from a battery attached to the electronic device 1, so when the battery is detached, the electronic device 1 is supplied with no power. For a battery having a remaining energy level thereof stored in the remaining battery energy level memory 5, the remaining energy level should be updated upon detachment of the battery.

For this implementation, there may be a method of detecting a detachment of battery, to effect storage of remaining energy level before the detachment. This method needs a switch or the like to detect a battery to be detached, with a complicated structure, constituting a cause of increased cost, as well.

To this point, there is a remaining energy level of battery in service updated at small intervals of predetermined time T, as described, without needing a remaining energy level to be stored anew upon detachment of battery, thus eliminating the need of a switch or the like to detect a battery to be detached.

Subsequently, at the step S480, the controller 13 works to have the capacity and remaining energy level adder 6 calculate a total remaining battery energy level ‘CR all’ as a sum of a previously calculated ‘CR mem’ and the remaining energy level ‘CR’ of the battery in service 20.

Subsequently, at a step S490, the controller 13 employs a capacity ‘CA of the battery in service 20, the remaining energy level ‘CR’ of the battery in service 20, a previously determined total battery capacity ‘CA all’, the total remaining energy level ‘CR all’, etc., for driving the screen display 7 to display thereon remaining energy levels of the battery in service 20 and other stored batteries, as well as a sum of them. Afterward, the flow again goes to the step S430 to repeat subsequent processes.

Description is now made of examples of remaining energy levels displayed on the screen display 7.

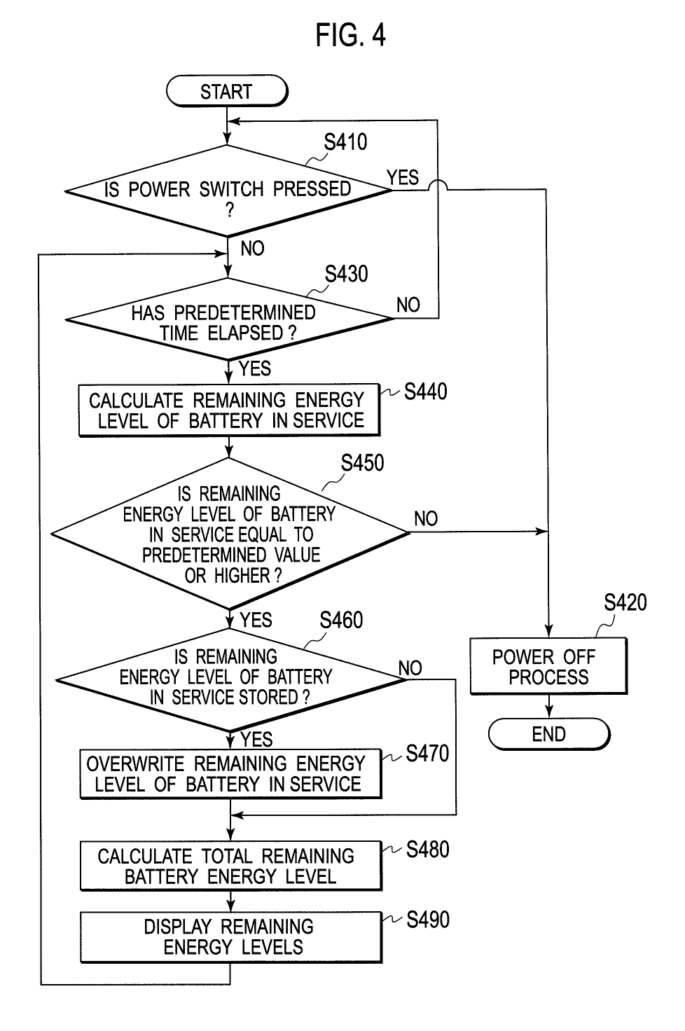

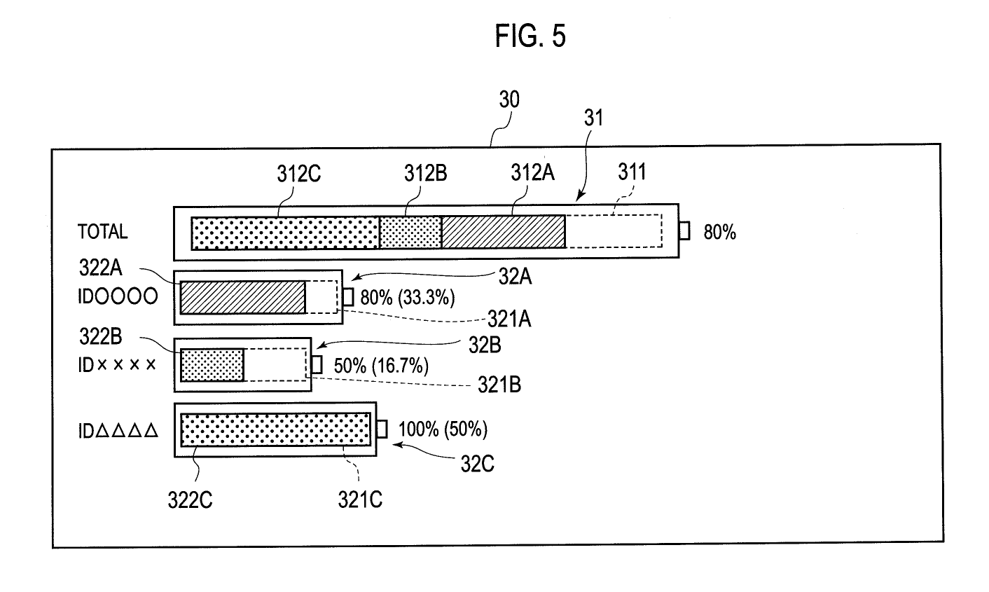

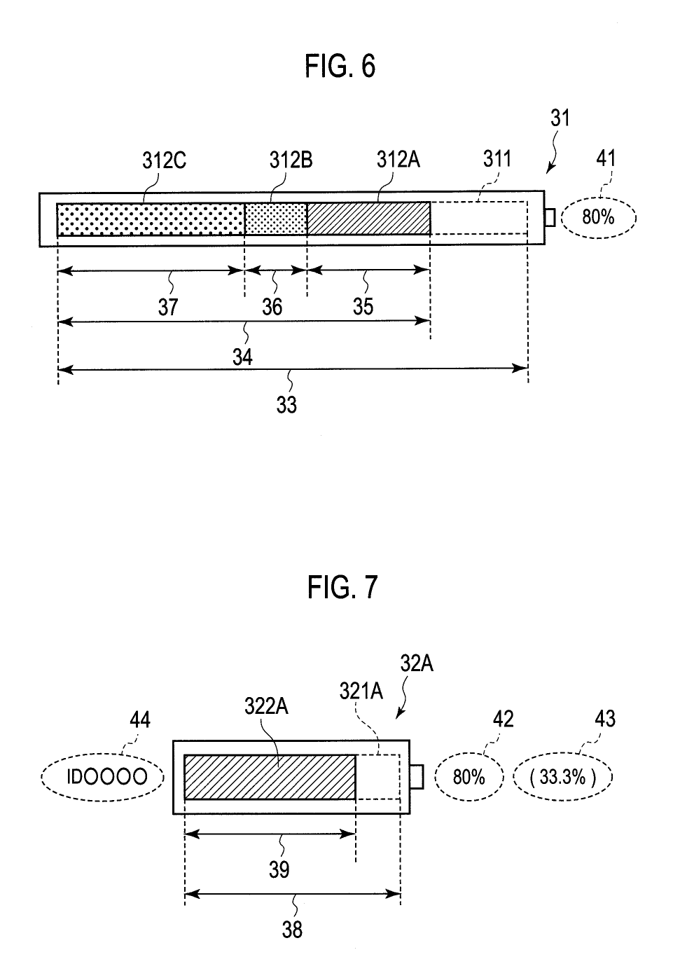

FIG. 5 illustrates an example of remaining energy level display screen according to the first embodiment, for three batteries to have remaining energy levels thereof displayed. FIG. 6 is an illustration of an example of total capacity and remaining energy level display graphic in FIG. 5, and FIG. 7, an illustration of an example of individual capacity and remaining energy level display graphic in FIG. 5.

As illustrated in FIG. 5, there is a remaining energy level display screen 30 displaying a total capacity and remaining energy level display graphic 31 indicating a total battery capacity and a total remaining battery energy level of three batteries, and a set of individual capacity and remaining energy level display graphics 32A to 32C each indicating a capacity and a remaining energy level of a battery.

Here, the individual capacity and remaining energy level display graphics 32A to 32C correspond to batteries A to C, respectively, assuming capacities of the batteries under relationships, such that a capacity of the battery C>a capacity of the battery A>a capacity of the battery B, and a ratio of remaining energy level to capacity of each battery to be 80% for the battery A, 50% for the battery B, and 100% for the battery C.

FIG. 5 illustrates an example of remaining energy level display screen including remaining energy levels displayed in the order of initial storage to the remaining battery energy level memory 5, as an example having the remaining energy levels stored in the order of battery A→battery B→battery C, while the battery A is put in service.

As illustrated in FIG. 5, the total capacity and remaining energy level display graphic 31 displayed is comprised of a total capacity display portion 311 indicating a total of capacities of the batteries A to C, and remaining energy level display parts 312A to 312C indicating remaining energy levels of the batteries A to C. The remaining energy level display parts 312A to 312C are serially connected to display, constituting a total remaining energy level display portion indicating a total of remaining energy levels of the batteries A to C. The individual capacity and remaining energy level display graphics 32A to 32C displayed are comprised of capacity display portions 321A to 321C indicating capacities of corresponding batteries A to C, and remaining energy level display parts 322A to 322C indicating associated remaining energy levels, respectively.

The total capacity and remaining energy level display graphic 31 and the individual capacity and remaining energy level display graphics 32A to 32C are displayed with dimensions commensurate with corresponding capacities, respectively, so they are displayed such that the total capacity display portion 311 of the total capacity and remaining energy level display graphic 31 has a length 33 thereof equal to a sum of lengths of the capacity display portions 321A to 321C of the individual capacity and remaining energy level display graphics 32A to 32C. The lengths of the capacity display portions 321A to 321C of the individual capacity and remaining energy level display graphics 32A to 32C displayed are lengthwise commensurate with capacities of the batteries A to C.

The remaining energy level display parts 312A to 312C are displayed with dimensions commensurate with corresponding remaining energy levels, respectively, so they are displayed such that the remaining energy level display parts 312A to 312C have lengths 35 to 37 thereof commensurate with magnitudes of remaining energy levels of the batteries A to C. Further, the remaining energy level display parts 322A to 322C of the individual capacity and remaining energy level display graphics 32A to 32C displayed have lengths thereof equal to the lengths 35 to 37 of the remaining energy level display parts 312A to 312C of the total capacity and remaining energy level display graphic 31.

Moreover, the total capacity and remaining energy level display graphic 31 has a ratio between the length 33 of the total capacity display portion 311 and a total length 34 of the remaining energy level display parts 312A to 312C, displayed to be equal to a ratio between the total battery capacity and the total remaining battery energy level of the three batteries. Further, the individual capacity and remaining energy level display graphic 32A has a ratio between a length 38 of the capacity display portion 321A and a length 39 of the remaining energy level display part 322A, displayed to be equal to a ratio between capacity and remaining energy level of the battery A. This is true in the individual capacity and remaining energy level display graphics 32B and 32C, as well.

The remaining energy level display parts 312A to 312C of the total capacity and remaining energy level display graphic 31 and the remaining energy level display parts 322A to 322C of the individual capacity and remaining energy level display graphics 32A to 32C are displayed in corresponding modes, respectively, with correspondence relationships visible to user.

Further, they are displayed in such modes that enable the remaining energy level display parts 312A and 322A of the battery in service A to be distinguished from the remaining energy level display parts 312B, 322B and 312C, 322C of the other batteries B and C. In the illustrated example, the remaining energy level display parts 312A and 322A are displayed by oblique lines representing remaining energy levels of the battery in service A, as a mode permitting their distinction at a glance relative to the remaining energy level display parts 312B, 322B and 312C, 322C.

The individual capacity and remaining energy level display graphics 32A to 32C are arrayed in the order of individual capacity and remaining energy level display graphics 32A, 32B, and 32C from the top in accordance with the order of initial storage of corresponding batteries A to C to the remaining battery energy level memory 5.

In the total capacity and remaining energy level display graphic 31, the remaining energy level display parts 312A to 312C are serially arranged such that the remaining energy level display part 312A corresponding to the battery in service A is disposed at a right-hand end in the figure, and that between the remaining energy level display parts 312B and 312C corresponding to the batteries out of service B and C, the remaining energy level display part 312B of the battery B being earlier in the order of storage of remaining energy level is disposed nearer in position to the remaining energy level display part 312A of the battery A. As the remaining energy level of the battery A is decreased, the remaining energy level display part 312A is contracted with a distal end thereof moved leftward from the right-hand end, displaying a decrease of remaining energy level visible to user with ease.

There is a remaining energy level ratio display region 41 neighboring the total capacity and remaining energy level display graphic 31, for displaying a ratio of the total remaining battery energy level to the total battery capacity of the three batteries (80% in the illustrated example).

There is a combination of remaining energy level ratio display regions 42 and 43 neighboring the individual capacity and remaining energy level display graphic 32A, for displaying combination of a ratio of a remaining battery energy level to the capacity of the battery A (80% in the illustrated example in FIG. 7), and a ratio of the remaining battery energy level of the battery A to the total remaining battery energy level (33.3% in the illustrated example in FIG. 7), respectively. Further, there is a battery ID display region 44 for displaying a battery ID of the battery A. Also for the individual capacity and remaining energy level display graphics 32B and 32C, similar contents are displayed.

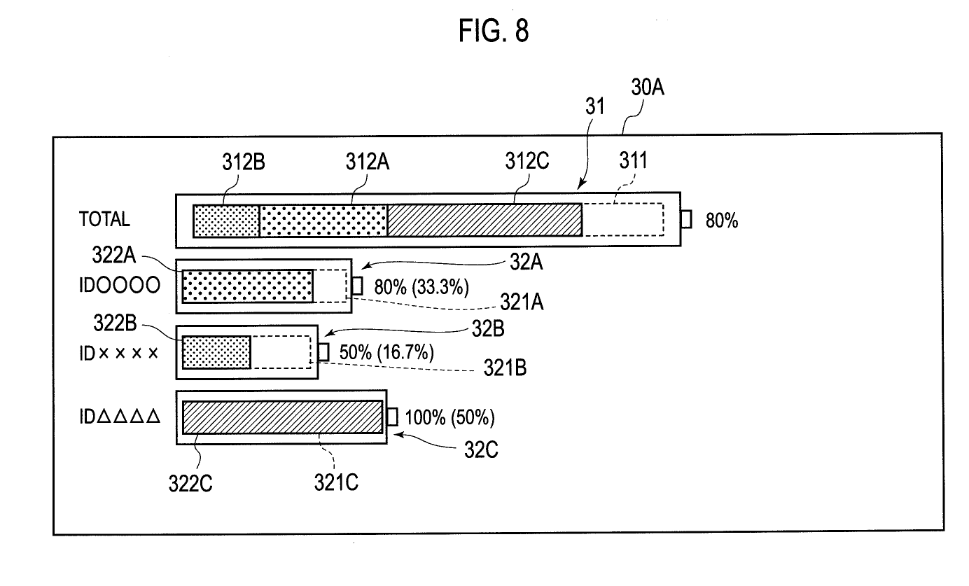

FIG. 8 illustrates another example of remaining energy level display screen according to the first embodiment. It is noted that in FIG. 8, those parts duplicating FIG. 5 are designated by like reference signs, eliminating redundant description.

FIG. 8 illustrates a remaining energy level display screen 30A, as an example of remaining energy level display screen for adaptation to display remaining energy levels in the order of storage to the remaining battery energy level memory 5, like the remaining energy level display screen 30 illustrated in FIG. 5, while it is different from the remaining energy level display screen 30 in FIG. 5 in that the battery in service is a battery C.

In FIG. 8, remaining energy level display parts 312C and 322C of the battery C are displayed by oblique lines representing remaining energy levels of a battery in service, as a mode permitting their distinction at a glance relative to remaining energy level display parts 312B, 322B and 312C, 322C of batteries A and B.

In a total capacity and remaining energy level display graphic 31 on the remaining energy level display screen 30A, the remaining energy level display parts 312A to 312C are serially arranged such that the remaining energy level display part 312C corresponding to the battery in service C is disposed at a right-hand end in the figure, and that between the remaining energy level display parts 312A and 312B corresponding to the batteries out of service B and C, the remaining energy level display part 312A of the battery A being earlier in the order of storage of remaining energy level is disposed nearer in position to the remaining energy level display part 312C of the battery C.

Such being the case, in the total capacity and remaining energy level display graphic 31, there is a remaining energy level of a battery in service disposed at a right-hand end irrespective of the order of storage, thereby displaying a decrease of remaining energy level visible to user with ease.

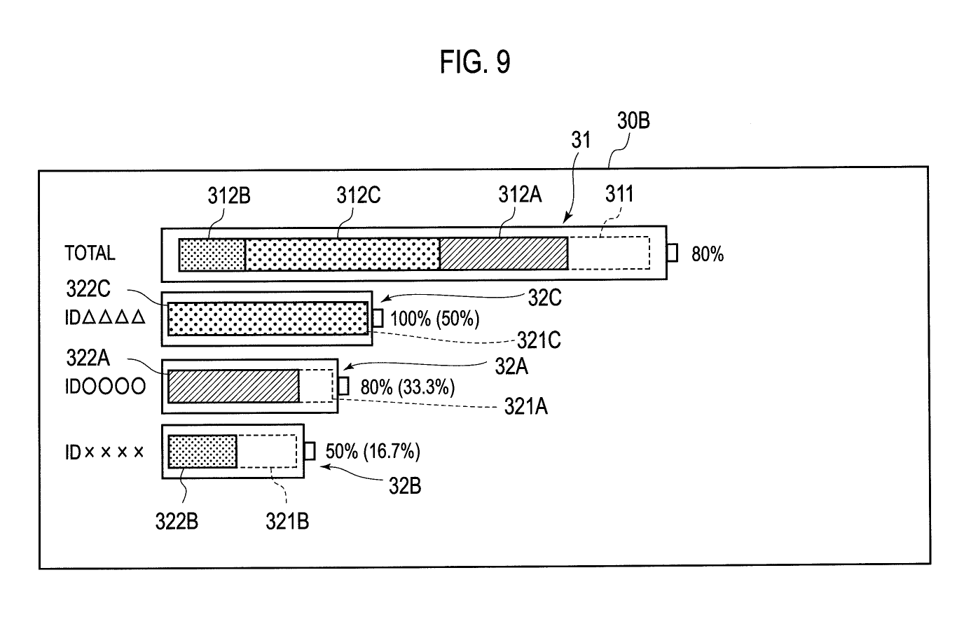

FIG. 9 illustrates still another example of remaining energy level display screen according to the first embodiment. It is noted that in FIG. 9, those parts duplicating FIG. 5 are designated by like reference signs, eliminating redundant description.

FIG. 9 illustrates an example of remaining energy level display screen for adaptation with a battery A in service, to display remaining energy levels in the order of magnitude, such that individual capacity and remaining energy level display graphics 32A to 32C are arrayed in the order of individual capacity and remaining energy level display graphics 32C, 32A, and 32B from the top.

As illustrated in FIG. 9, in a total capacity and remaining energy level display graphic 31 on a remaining energy level display screen 30B, there are remaining energy level display parts 312A to 312C serially arranged such that the remaining energy level display part 312A corresponding to the battery in service A is disposed at a right-hand end in the figure, and that between the remaining energy level display parts 312B and 312C corresponding to the batteries out of service B and C, the remaining energy level display part 312C of the battery C being greater in remaining energy level is disposed nearer in position to the remaining energy level display part 312A of the battery A.

Such the remaining energy level display screen 30B permits user to grasp remaining energy levels of batteries in a facilitated manner.

The remaining energy level display screens 30, 30A, and 30B described are shown as examples simultaneously displaying both of a total capacity and remaining energy level display graphic 31 and a combination of individual capacity and remaining energy level display graphics 32A to 32C, while they may be adapted to display no more than a total capacity and remaining energy level display graphic 31, or no more than a combination of individual capacity and remaining energy level display graphics 32A to 32C. It however is preferable to display both, as a matter of course. They may be adapted to selectively display a total capacity and remaining energy level display graphic 31 and a combination of individual capacity and remaining energy level display graphics 32A to 32C. Although graphic is preferable, the representation may be simply made by use of a numeral character sequence directly indicating capacities such as 50% and 80%. They can do well with adaptation to display a first set of information on remaining energy level representative of a remaining energy level of a battery in service 20, and a second set of information on remaining energy level representative of remaining energy levels of batteries out of service else than the battery in service 20 having remaining energy levels thereof stored in the remaining battery energy level memory 5.

Description is now made of examples of messages to be displayed.

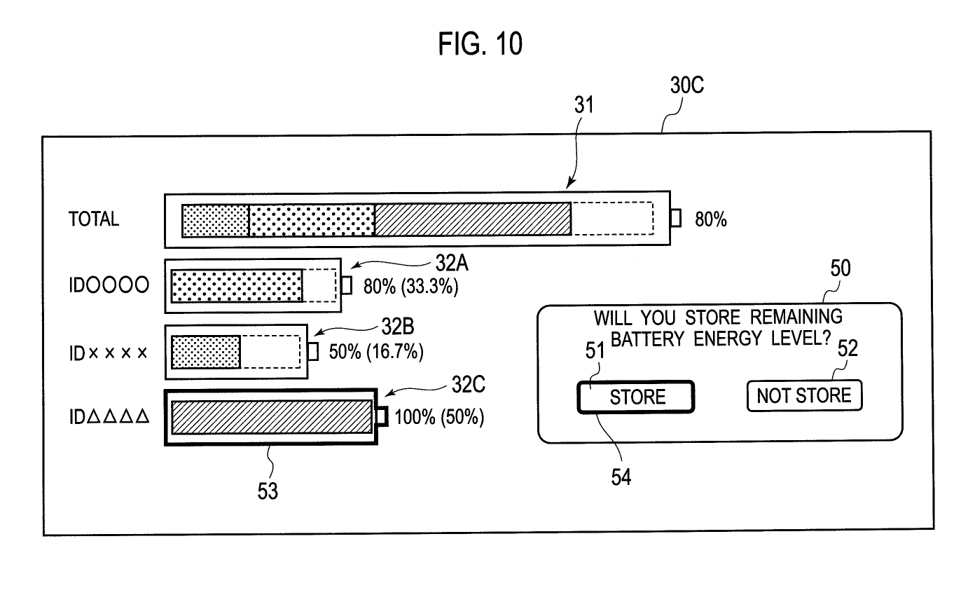

FIG. 10 illustrates an example of remaining energy level display screen displaying a message prompting a selection by user to or not to store a remaining energy level of a battery in service in the remaining battery energy level memory 5. It is noted that in FIG. 10, those parts duplicating FIG. 5 are designated by like reference signs, eliminating redundant description.

For a state of battery in service with small energy remaining, there should be an option to be available not to store the remaining energy level of the battery, as described at the step S150 in FIG. 2B. In this regard, there should be a message displayed on the screen display 7, prompting a selection by user to or not to store a remaining energy level of a battery in service in the remaining battery energy level memory 5.

FIG. 10 illustrates a remaining energy level display screen 30C adapted, by displaying an additional message box 50 on the remaining energy level display screen 30A illustrated in FIG. 8, to prompt a selection by user to or not to store a remaining energy level of a battery in service in the remaining battery energy level memory 5. The message box 50 displays combination of a “STORE” button 51 for instruction ‘to store’, and a “NOT STORE” button 52 for instruction ‘not to store’.

The operation input interface 9 is operable by user, to move a selection frame 53 for selecting a battery for storage of remaining energy level and a selection frame 54 for selecting the “STORE” button 51 or the “NOT STORE” button 52, to desirable positions on the remaining energy level display screen 30C, to operate for decision to have the electronic device 1 behave in accordance with an option.

Description is now made of deletion of a remaining energy level stored in the remaining battery energy level memory 5.

User may depend on a condition of use of the electronic device 1, to determine the number of batteries to carry around, leaving a battery or batteries not carried, of which level or levels of energy remaining, if displayed on the screen display 7, should be deleted. This applies also to remaining energy level indication of a battery or batteries of which energy has run out.

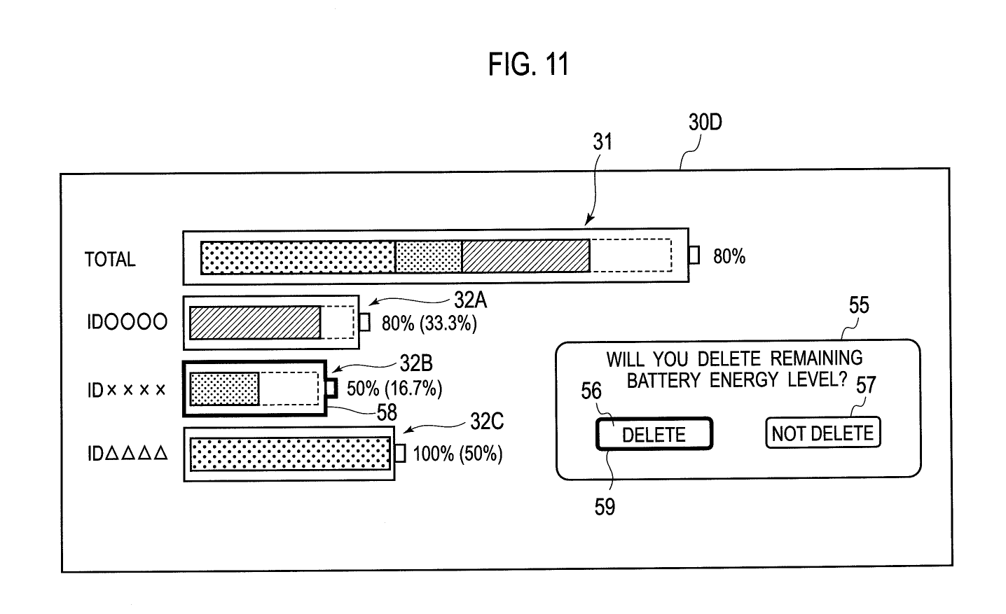

FIG. 11 illustrates an example of remaining energy level display screen displaying a message for deletion of a remaining energy level stored in the remaining battery energy level memory 5. It is noted that in FIG. 11, those parts duplicating FIG. 5 are designated by like reference signs, eliminating redundant description.

FIG. 11 illustrates a remaining energy level display screen 30D adapted, by displaying an additional message box 55 on the remaining energy level display screen 30 illustrated in FIG. 5, to prompt a selection by user to or not to delete a remaining energy level of a selected battery from the remaining battery energy level memory 5. The message box 50 displays combination of a “DELETE” button 56 for instruction ‘to delete’, and a “NOT DELETE” button 57 for instruction ‘not to delete’.

The operation input interface 9 is operable by user, to move a selection frame 58 for selecting a battery for deletion of remaining energy level and a selection frame 59 for selecting the “DELETE” button 56 or the “NOT DELETE” button 57, to desirable positions on the remaining energy level display screen 30D, to operate for decision.

With operations by user selecting a single battery, selecting the “DELETE” button 56, the controller 13 works to delete the selected battery's remaining energy level, battery ID, and remaining energy level storage time from the remaining battery energy level memory 5, and control the screen display 7 to delete from the remaining energy level display screen 30D a remaining energy level display part of a total capacity and remaining energy level display graphic 31 and an individual capacity and remaining energy level display graphic that correspond to the selected battery.

Description is now made of an example of battery ID displayed on a battery.

The screen display 7 has battery IDs displayed thereon in correspondence to individual capacity and remaining energy level display graphics of batteries. User is allowed to select a battery next to use on the basis of a displayed remaining energy level and battery ID. In this respect, the battery itself should have a visible battery ID displayed thereon.

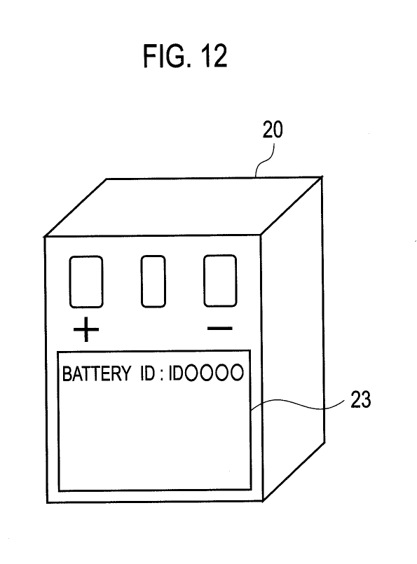

FIG. 12 illustrates an example of battery ID displayed on a battery. Shown in FIG. 12 is a battery 20 provided at the front with a label 23 carrying a printed battery ID. The battery ID on the label 23 is displayed in the same mode as a battery ID displayed in correspondence to an individual capacity and remaining energy level display graphic on the screen display 7.

As will be seen from the foregoing description, according to the first embodiment, there is a set of remaining energy levels of batteries subjected to attachment to an electronic device 1 and stored in a remaining battery energy level memory 5, permitting not simply a remaining energy level of a battery in service, but also remaining energy levels of batteries out of service, to be added up to display on a screen display 7, allowing for user to grasp a total remaining energy level with ease.

It is noted that in FIG. 5 to FIG. 11, as a method of discriminating a battery in service, there is use of oblique lines indicating a remaining energy level of the battery in service, which however is not restrictive, so there may be use of differences such as in color, pattern, gloss, or texture for distinction.

Further, there is combination of a total capacity and remaining energy level display graphic 31 and a set of individual capacity and remaining energy level display graphics 32A to 32C having their relationships in position for display as illustrated in FIG. 5 and FIG. 8 to FIG. 11, which are not restrictive. For instance, in FIG. 9 illustrating an example of set of individual capacity and remaining energy level display graphics 32A to 32C arrayed in descending order from the top in the order of magnitude of remaining energy level, they may well be arrayed in ascending order from the top.

### Second Embodiment

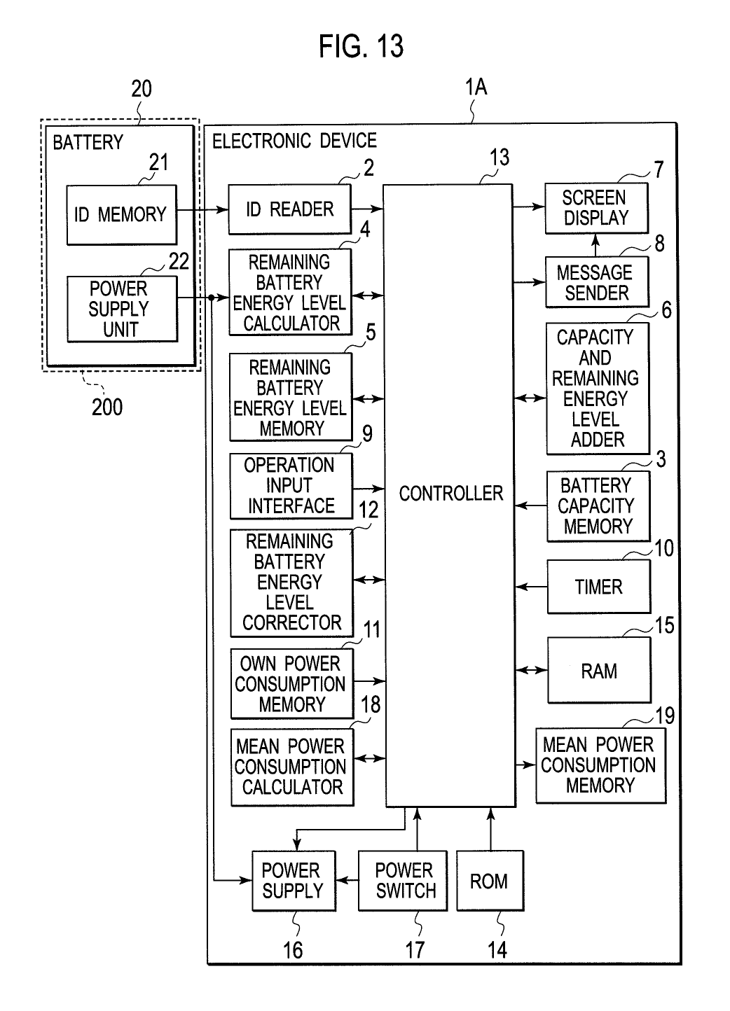

FIG. 13 is a block diagram of configuration of an electronic device according to a second embodiment of the present invention. It is noted that among constituent elements of the second embodiment shown FIG. 13, similar constituent elements to the first embodiment are designated by like reference signs, eliminating redundant description.

As shown in FIG. 13, according to the second embodiment, there is an electronic device 1A including combination of a mean power consumption calculator 18 and a mean power consumption memory 19, added to the electronic device 1 according to the first embodiment shown in FIG. 1.

The mean power consumption calculator 18 is configured to calculate a mean power consumption of the electronic device 1A from a decrease in value per unit time of remaining energy level calculated at a remaining battery energy level calculator 4. It is noted that the mean power consumption calculator 18 may be configured to calculate a mean of power consumption from electric energy per unit time supplied from a power supply unit 22 of a battery 20 to the electronic device 1A.

The mean power consumption memory 19 is configured to store therein a mean power consumption of the electronic device 1A calculated at the mean power consumption calculator 18.

There is a controller 13 configured to function as an operable time calculator for use of remaining energy levels of batteries, a total remaining battery energy level, and a mean power consumption stored in the mean power consumption memory 19, to calculate respective operable times by the remaining energy levels of batteries and the total remaining battery energy level. The controller 13 is configured to have a screen display 7 display, among others, later-described combination of a total time display graphic and individual time display graphics or the like representative of operable times of the electronic device 1A by remaining energy levels of batteries.

Description is now made of actions of the electronic device 1A according to the second embodiment.

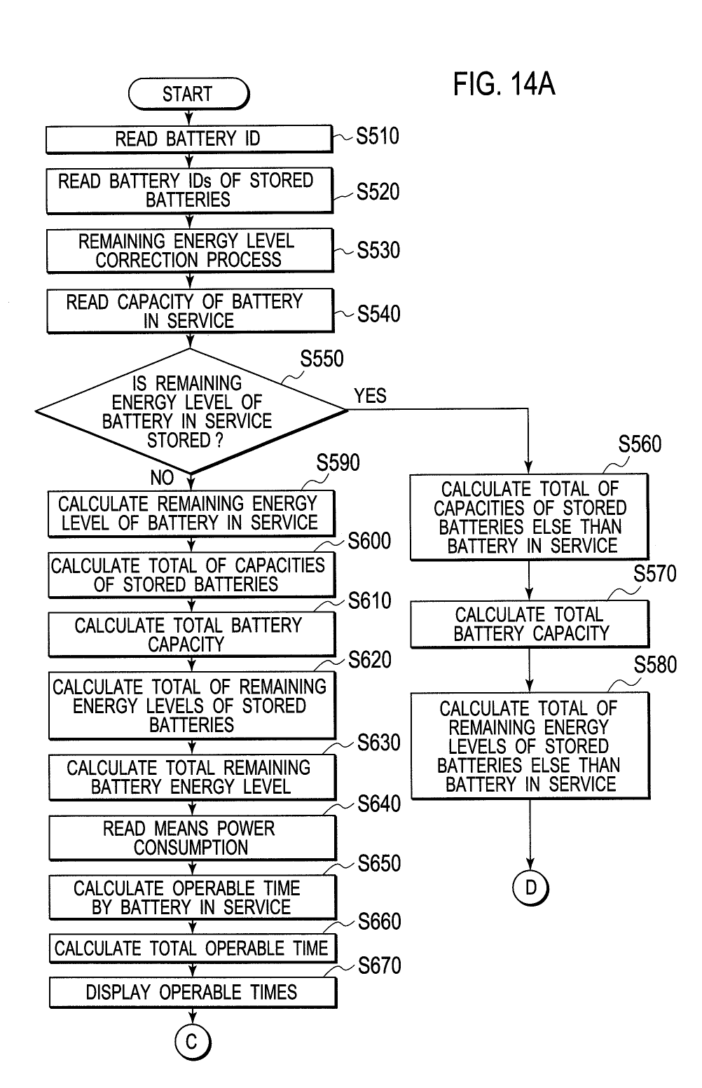

FIG. 14A and FIG. 14B show flowcharts of actions of the electronic device 1A. In FIG. 14A and FIG. 14B, processes at steps S510 to S630 and S680 to S740 are similar to those at the steps S10 to S220 in flowcharts of FIG. 2A and FIG. 2B in the first embodiment described, so redundant description is omitted, and description is mainly made of steps S640 to S670, and step S750 being different from the first embodiment.

In FIG. 14A, at a step S640, the controller 13 reads a mean power consumption of the electronic device 1A, as it has been calculated in advance at the mean power consumption calculator 18 and stored in the mean power consumption memory 19.

Subsequently, at a step S650, the controller 13 works on bases of the mean power consumption of the electronic device 1A and a remaining energy level ‘CR’ of a battery in service 20 calculated at a step S590, to calculate an operable time by the remaining energy level ‘CR’ of the battery in service 20.

Subsequently, at a step S660, the controller 13 works on bases of the mean power consumption of the electronic device 1A and a total remaining battery energy level ‘CR all’ calculated at a step S630, to calculate a total operable time by the total remaining battery energy level ‘CR all’. The controller 13 works on bases of remaining energy levels of stored batteries stored in a remaining battery energy level memory 5 and the mean power consumption of the electronic device 1A, to calculate operable times by remaining energy levels of the stored batteries.

Subsequently, at a step S670, the controller 13 employs thus determined operable time by remaining energy level ‘CR’ of the battery in service 20, total operable time by the total remaining energy level ‘CR all’, operable times by remaining energy levels of stored batteries, etc., for driving the screen display 7 to display thereon operable times of the battery in service 20 and other stored batteries, as well as a sum of them. For the operable times displayed, the mode of display employed is similar to that in an operable time display process to be described later on.

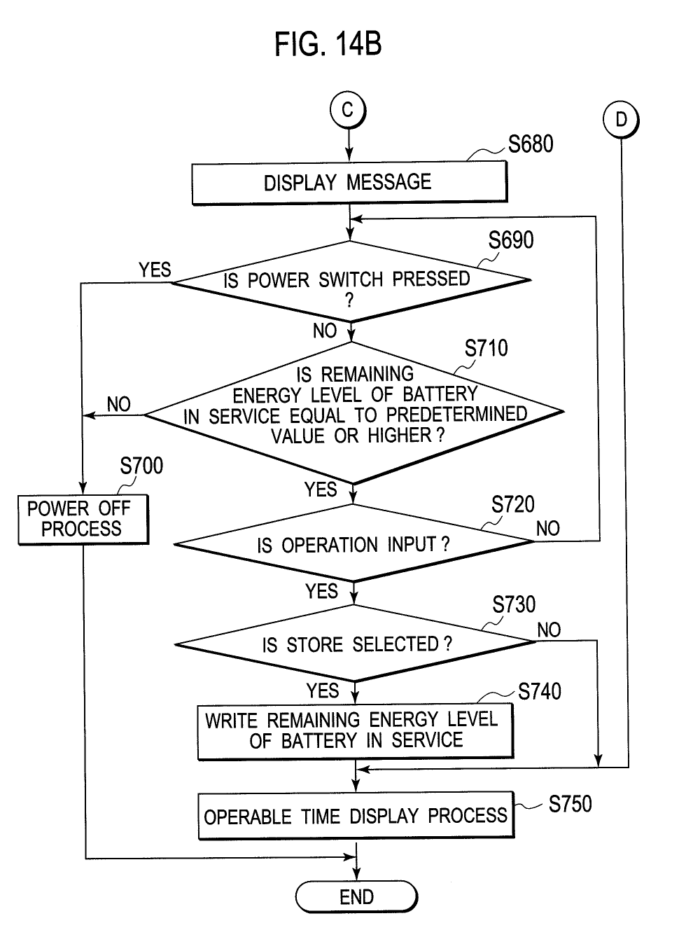

In FIG. 14B, at the step S750, the controller 13 implements an operable time display process. For the operable time display process at the step S750, a procedure will be described with reference to a flowchart shown in FIG. 15.

In FIG. 15, processes at steps S810 to S880 are similar to those at the steps S10 to S480 in flowchart of FIG. 4 in the first embodiment described, so redundant description is omitted, and description is mainly made of steps S890 to S920 being different from the first embodiment.

At the step S890, the controller 13 reads a mean power consumption of the electronic device 1A stored in the mean power consumption memory 19.

Subsequently, at a step S900, the controller 13 works on bases of the mean power consumption of the electronic device 1A and a remaining energy level ‘CR’ of a battery in service 20 calculated at a step S840, to calculate an operable time by the remaining energy level ‘CR’ of the battery in service 20.

Subsequently, at a step S910, the controller 13 works on bases of the mean power consumption of the electronic device 1A and a total remaining battery energy level ‘CR all’ calculated at a step S880, to calculate a total operable time by the total remaining battery energy level ‘CR all’.

Then, at a step S920, the controller 13 employs thus determined operable time by remaining energy level ‘CR’ of the battery in service 20, total operable time by the total remaining energy level ‘CR all’, etc., for driving the screen display 7 to display thereon operable times of the battery in service 20 and other stored batteries, as well as a sum of them. Afterward, the flow again goes to a step S830, to repeat subsequent processes.

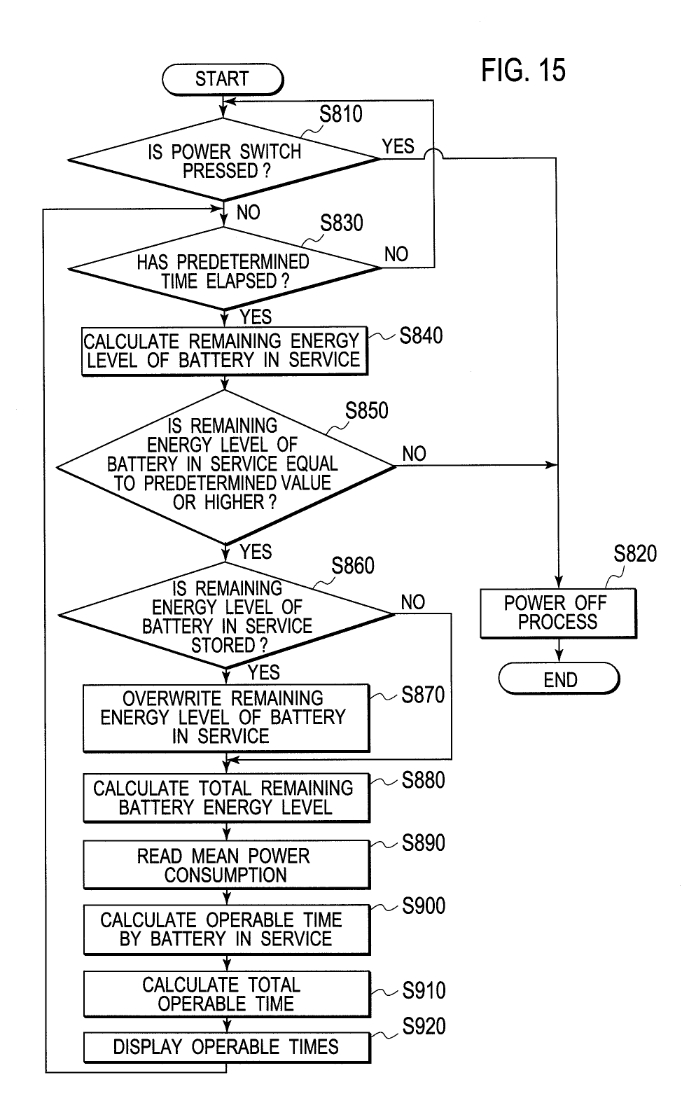

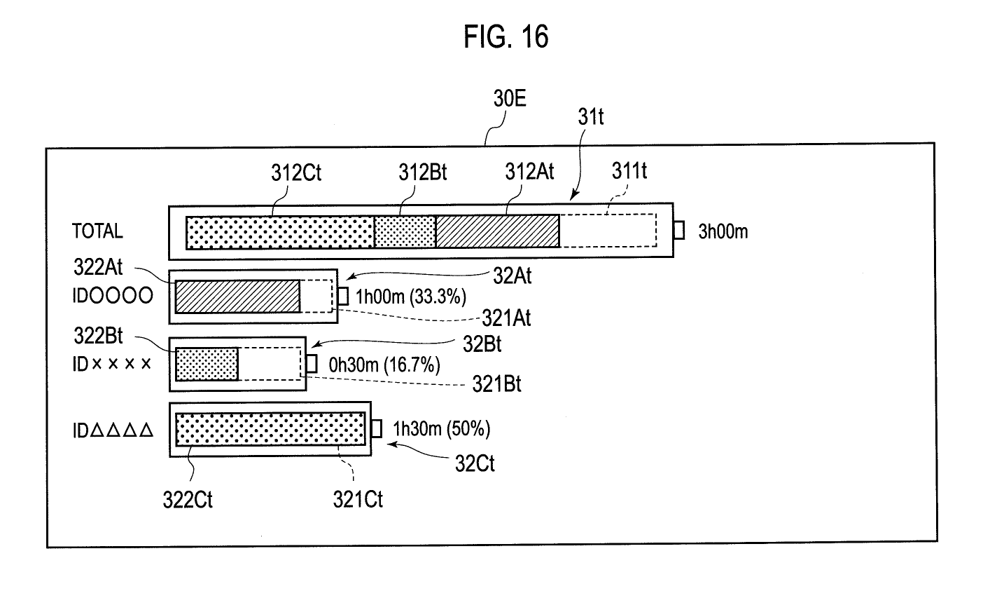

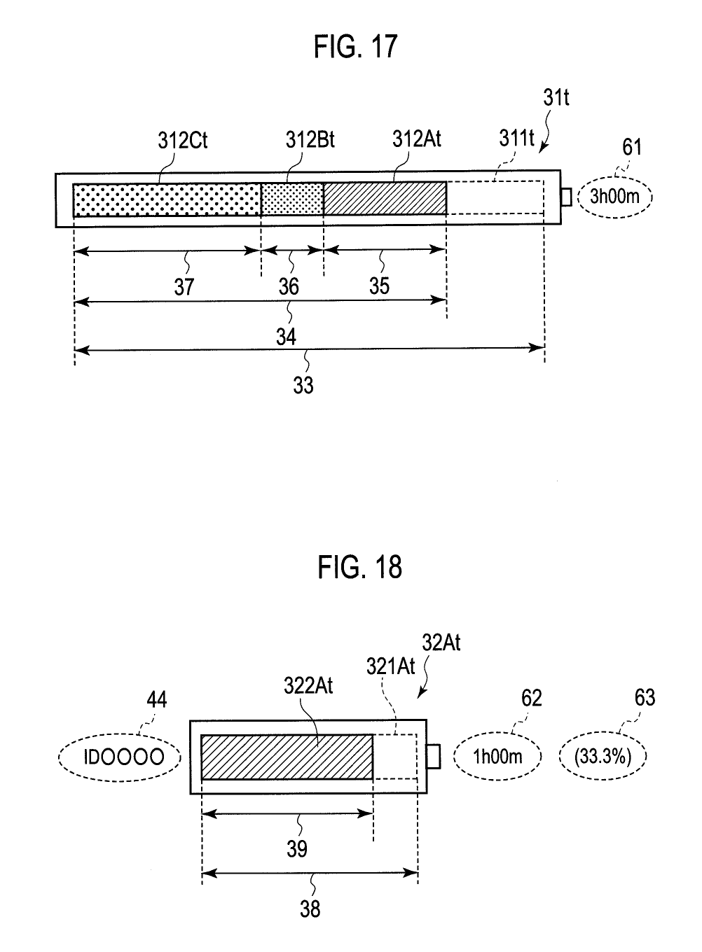

FIG. 16 illustrates an example of operable time display screen according to the second embodiment. FIG. 17 is an illustration of a total operable time display graphic in FIG. 16, and FIG. 18, an illustration of an individual operable time display graphic in FIG. 16. It is noted that in FIG. 16 to FIG. 18, those parts duplicating FIG. 5 to FIG. 7 are designated by like reference signs, eliminating redundant description

FIG. 16 illustrates an operable time display screen 30E, as an example of operable time display screen in which remaining energy levels in FIG. 5 are replaced by operable times of the electronic device 1A based on remaining energy levels, and the operable times are displayed in accordance with the order of storage of remaining energy levels to the remaining battery energy level memory 5. FIG. 16 illustrates an example having remaining energy levels stored in the order of battery A→battery B→battery C, and a battery A put in service, to display 1 hour (1 h00 m) as an operable time by remaining energy level of the battery in service A, 30 minutes (0 h30 m) as an operable time by remaining energy level of the battery B, and 1 hour 30 minutes (1 h30 m) as an operable time by remaining energy level of the battery C.

As illustrated in FIG. 16, the operable time display screen 30E corresponds to the remaining energy level display screen 30 illustrated in FIG. 5, as the total capacity and remaining energy level display graphic 31 is replaced a total time display graphic 31t, and the individual capacity and remaining energy level display graphics 32A to 32C are replaced by individual time display graphics 32At to 32Ct.

The total time display graphic 31t is representative of an operable time of the electronic device 1A by a total capacity of the three batteries (as an operable time of the electronic device 1A when all the three batteries are in full charge), and an operable time of the electronic device 1A by a total remaining battery energy level. The individual time display graphics 32At to 32Ct are individually representative of an operable time of the electronic device 1A by a total capacity of a respective battery (as an operable time of the electronic device 1A when the respective battery is in full charge), and an operable time of the electronic device 1A by a remaining energy level.

The operable time display screen 30E corresponds to the remaining energy level display screen 30 illustrated in FIG. 5, as replacements are made from the total capacity display portion 311 to a total time display portion 311t, from the remaining energy level display parts 312A to 312C to remaining time display parts 312At to 312Ct, from the capacity display parts 321A to 321C to individual time display parts 321At to 321Ct, and from the remaining energy level display parts 322A to 322C to remaining time display parts 322At to 322Ct, respectively.

The total time display portion 311t is representative of a total of operable times of the electronic device 1A by capacities of the batteries A to C (as an operable time of the electronic device 1A when the batteries A to C are all in full charge), and the remaining time display parts 312At to 312Ct are representative of operable times of the electronic device 1A by remaining energy levels of the batteries A to C, i.e., of corresponding batteries A to C. The remaining time display parts 312At to 312Ct are serially connected to display, constituting a total remaining time display portion representative of a total of operable times by remaining energy levels of the batteries A to C. The individual time display parts 321At to 321Ct are representative of operable times of the electronic device 1A by capacities of corresponding batteries A to C (as operable times of the electronic device 1A by the batteries A to C when the batteries are all in full charge), and the remaining time display parts 322At to 322Ct are representative of operable times of the electronic device 1A by remaining energy levels of corresponding batteries A to C.

As illustrated by FIG. 17, there is an operable time display region 61 neighboring the total time display graphic 31t, for displaying an operable time by a total remaining battery energy level of the three batteries (3 hours in the illustrated example).

As illustrated by FIG. 18, there is a combination of an operable time display region 62 and an operable time ratio display region 63, neighboring the individual time display graphic 32At, the operable time display region 62 displaying an operable time by a remaining energy level of the battery A (1 hour in the illustrated example in FIG. 18), the operable time ratio display region 63 displaying a ratio of the operable time by the remaining energy level of the battery A to the operable time by the total remaining battery energy level (33.3% in the illustrated example in FIG. 18). As illustrated by FIG. 16, also for the individual time display graphics 32Bt and 32Ct, similar contents are displayed.

As will be seen from the foregoing description, according to the second embodiment, in addition to similar effects to the first embodiment, user is allowed to recognize status of energy remaining in batteries, as a set of information on operable times.

It is noted that FIG. 16 shows an example having individual time display graphics 32At to 32Ct arrayed from the top in the order of storage of remaining energy level, which may be arranged to display in the order of magnitude of remaining energy level (as length of operable time), like the first embodiment.

Also in the second embodiment, there is shown an example simultaneously displaying both of a total time display graphic 31t and a combination of individual time display graphics 32At to 32Ct, while it may be adapted to display no more than a total time display graphic 31t, or no more than a combination of individual time display graphics 32At to 32Ct. It however is preferable to display both, as a matter of course. There may be adaptation to selectively display a total time display graphic 31t and a combination of individual time display graphics 32At to 32Ct. Although graphic is preferable, the representation may be simply made by use of a numeral character sequence directly indicating operable times (remaining times) such as 1 h00 m and 0 h30 m. They can do well with adaptation to display a first set of information on operable time representative of an operable time by a remaining energy level of a battery in service 20, and a second set of information on operable time representative of operable times by remaining energy levels of batteries out of service else than the battery in service having remaining energy levels thereof stored in the remaining battery energy level memory 5.

Further, there may well be use of graphics having operable times simply substituting for remaining energy levels indicated in FIG. 5 in the first embodiment.

### INDUSTRIAL APPLICABILITY

The present invention is applicable to arbitrary electronic devices to be driven with batteries, encompassing among others mobile electronics such as video cameras, digital cameras, notebook PCs, cellular telephones, etc.

1-58. (canceled)

59. An electronic device operable with battery-derived power, the electronic device comprising:
an ID reader configured to read a battery ID of a battery in service attached to the electronic device;
a remaining battery energy level calculator configured to calculate a remaining energy level of the battery in service;
a remaining battery energy level memory configured to store therein remaining energy levels of batteries subjected to selective attachment to the electronic device, respectively associated with battery IDs thereof;
a screen display;
a message sender configured to work for a new battery not stored in the remaining battery energy level memory, attached to the electronic device, to display on the screen display a message prompting a selection by user to or not to store a remaining energy level of the new battery in the remaining battery energy level memory;
a remaining energy level storage controller configured to work for an instruction signal input for storage of remaining energy level of the new battery, to have a remaining energy level of the new battery calculated by the remaining battery energy level calculator, associated with an ID of the new battery, stored in the remaining battery energy level memory; and
a display controller configured for control to display on the screen display a first set of information on remaining energy level representative of the remaining energy level of the battery in service, and a second set of information on remaining energy level representative of remaining energy levels of batteries out of service else than the battery in service having remaining energy levels thereof stored in the remaining battery energy level memory.

60. An electronic device operable with battery-derived power, the electronic device comprising:
an ID reader configured to read a battery ID of a battery in service attached to the electronic device;
a remaining battery energy level calculator configured to calculate a remaining energy level of the battery in service;
a remaining battery energy level memory configured to store therein remaining energy levels of batteries subjected to selective attachment to the electronic device, respectively associated with battery IDs thereof;
an operable time calculator configured to work on bases of respective remaining energy levels of the batteries, to calculate operable times for the electronic device to be operable by the batteries, respectively;
a screen display;
a message sender configured to work for a new battery not stored in the remaining battery energy level memory, attached to the electronic device, to display on the screen display a message prompting a selection by user to or not to store a remaining energy level of the new battery in the remaining battery energy level memory;
a remaining energy level storage controller configured to work for an instruction signal input for storage of remaining energy level of the new battery, to have a remaining energy level of the new battery calculated by the remaining battery energy level calculator, associated with an ID of the new battery, stored in the remaining battery energy level memory; and
a display controller configured for control to display on the screen display a first set of information on operable time representative of an operable time by the battery in service, and a second set of information on operable time representative of operable times by batteries out of service else than the battery in service having remaining energy levels thereof stored in the remaining battery energy level memory.

61. The electronic device according to claim 59, further comprising
a battery capacity memory configured to store therein capacities of batteries of types applicable to the electronic device, associated with information on type of battery, wherein
the remaining battery energy level calculator is configured to use a capacity of battery stored in the battery capacity memory, to calculate a remaining energy level of battery.

62. The electronic device according to claim 59, wherein the remaining battery energy level memory is configured to store therein remaining energy level storage times of storage of respective remaining energy levels of the batteries, associated with battery IDs of the batteries.

63. The electronic device according to claim 62, further comprising a remaining energy level update controller configured to calculate a remaining energy level of the battery in service at a respective prescribed time, updating a remaining energy level of the battery in service stored in the remaining battery energy level memory to the remaining energy level calculated, and change a remaining energy level storage time of the battery in service stored in the remaining battery energy level memory to a time of update of the remaining energy level.

64. The electronic device according to claim 62, further comprising:
an own power consumption memory configured to have own power consumptions per unit time of batteries of types applicable to the electronic device, associated with information on type of battery, stored therein; and
a remaining battery energy level corrector configured to calculate a remaining energy level correction value based on an own power consumption per unit time and a difference between a current time and a remaining energy level storage time stored in the remaining battery energy level memory, and use the remaining energy level correction value to correct a remaining energy level of battery stored in the remaining battery energy level memory.

65. The electronic device according to claim 59, further comprising a remaining energy level deletion controller configured to work for an instruction signal input for deletion of remaining energy level of a single battery selected from batteries having remaining energy levels thereof stored in the remaining battery energy level memory, to have a remaining energy level and a battery ID of a battery instructed by the instruction signal, deleted from the remaining battery energy level memory.

66. The electronic device according to claim 59, wherein the display controller is configured to implement a control to have the first set of information on remaining energy level comprising a first display graphic representative of a remaining energy level of the battery in service, and the second set of information on remaining energy level comprising a second display graphic representative of remaining energy levels of the batteries out of service, individually displayed on the screen display.

67. The electronic device according to claim 66, wherein the display controller is configured to implement a control to display, on the screen display, battery IDs of respective batteries corresponding to the first and the second display graphic.

68. The electronic device according to claim 66, wherein the display controller is configured to implement a control to display:
the first display graphic comprising a capacity display part representative of a capacity of the battery in service, and a remaining energy level display part representative of a remaining energy level of the battery in service;
the second display graphic comprising a capacity display part representative of a capacity of a battery out of service, and a remaining energy level display part representative of a remaining energy level of the battery out of service; and
the capacity display parts and the remaining energy level display parts of the first and the second display graphic having dimensions thereof commensurate with associated capacities or remaining energy levels.

69. The electronic device according to claim 68, wherein the display controller is configured to implement a control to correspond to the first or the second display graphic, to have a ratio of the remaining energy level display part to the capacity display part, displayed on the screen display.

70. The electronic device according to claim 60, wherein the display controller is configured to implement a control to have the first set of information on operable time comprising a first numeral character sequence inclusive of numeral and character representative of an operable time by the battery in service, and the second set of information on operable time comprising a second numeral character sequence inclusive of numeral and character representative of operable times by the batteries out of service, individually displayed on the screen display.

71. The electronic device according to claim 70, wherein the display controller is configured to implement a control to display, on the screen display, battery IDs of respective batteries corresponding to the first and the second numeral character sequence.

72. The electronic device according to claim 60, wherein the display controller is configured to implement a control to have the first set of information on operable time comprising a first display graphic representative of an operable time by the battery in service, and the second set of information on operable time comprising a second display graphic representative of operable times by the batteries out of service, individually displayed on the screen display.

73. The electronic device according to claim 72, wherein the display controller is configured to implement a control to display, on the screen display, battery IDs of respective batteries corresponding to the first and the second display graphic.

74. The electronic device according to claim 72, wherein the display controller is configured to implement a control to display:
the first display graphic comprising a first display part representative of an operable time based on a capacity of the battery in service, and a second display part representative of an operable time based on a remaining energy level of the battery in service;
the second display graphic comprising a first display part representative of an operable time based on a capacity of a battery out of service, and a second display part representative of an operable time based on a remaining energy level of the battery out of service; and
the first display parts and the second display parts of the first and the second display graphic having dimensions thereof commensurate with associated operable times.

75. The electronic device according to claim 74, wherein the display controller is configured to implement a control to correspond to the first or the second display graphic, to have a ratio of the second display part to the first display part, displayed on the screen display.

76. An electronic device operable with battery-derived power, the electronic device comprising:
an ID reader configured to read a battery ID of a battery in service attached to the electronic device;
a remaining battery energy level calculator configured to calculate a remaining energy level of the battery in service;
a remaining battery energy level memory configured to store therein remaining energy levels of batteries subjected to selective attachment to the electronic device, respectively associated with battery IDs thereof;
a screen display;
a display controller configured for control to display on the screen display a first set of information on remaining energy level representative of the remaining energy level of the battery in service, and a second set of information on remaining energy level representative of remaining energy levels of batteries out of service else than the battery in service having remaining energy levels thereof stored in the remaining battery energy level memory; and
a capacity and remaining energy level adder configured to calculate a total battery capacity being a sum of a capacity of the battery in service and capacities of the batteries out of service, and calculate a total remaining battery energy level being a sum of a remaining energy level of the battery in service and remaining energy levels of the batteries out of service, wherein
the display controller is configured to implement a control to have a total capacity and remaining energy level display graphic comprising a total capacity display portion representative of the total battery capacity, and a total remaining energy level display portion representative of the total remaining battery energy level, displayed on the screen display.

77. The electronic device according to claim 76, wherein the total remaining energy level display portion of the total capacity and remaining energy level display graphic comprises a combination of a remaining energy level display part representative of the first set of information on remaining energy level and a remaining energy level display part representative of the second set of information on remaining energy level.

78. The electronic device according to claim 76, wherein the display controller is configured to implement a control to display the remaining energy level display part representative of the first set of information on remaining energy level and the remaining energy level display part representative of the second set of information on remaining energy level, having dimensions thereof commensurate with associated remaining energy levels.

79. The electronic device according to claim 76, wherein the display controller is configured to implement a control to have a ratio of the total remaining energy level display portion to the total capacity display portion, displayed on the screen display.

80. An electronic device operable with battery-derived power, the electronic device comprising:
an ID reader configured to read a battery ID of a battery in service attached to the electronic device;
a remaining battery energy level calculator configured to calculate a remaining energy level of the battery in service;
a remaining battery energy level memory configured to store therein remaining energy levels of batteries subjected to selective attachment to the electronic device, respectively associated with battery IDs thereof;
an operable time calculator configured to work on bases of respective remaining energy levels of the batteries, to calculate operable times for the electronic device to be operable by the batteries, respectively;
a screen display;
a display controller configured for control to display on the screen display a first set of information on operable time representative of an operable time by the battery in service, and a second set of information on operable time representative of operable times by batteries out of service else than the battery in service having remaining energy levels thereof stored in the remaining battery energy level memory; and
a capacity and remaining energy level adder configured to calculate a total battery capacity being a sum of a capacity of the battery in service and capacities of the batteries out of service, and calculate a total remaining battery energy level being a sum of a remaining energy level of the battery in service and remaining energy levels of the batteries out of service, wherein
the display controller is configured to implement a control to have a numeral character sequence inclusive of numeral and character representative of an operable time for the electronic device to be operable with the total remaining battery energy level, displayed on the screen display.

81. An electronic device operable with battery-derived power, the electronic device comprising:
an ID reader configured to read a battery ID of a battery in service attached to the electronic device;
a remaining battery energy level calculator configured to calculate a remaining energy level of the battery in service;
a remaining battery energy level memory configured to store therein remaining energy levels of batteries subjected to selective attachment to the electronic device, respectively associated with battery IDs thereof;
an operable time calculator configured to work on bases of respective remaining energy levels of the batteries, to calculate operable times for the electronic device to be operable by the batteries, respectively;
a screen display;
a display controller configured for control to display on the screen display a first set of information on operable time representative of an operable time by the battery in service, and a second set of information on operable time representative of operable times by batteries out of service else than the battery in service having remaining energy levels thereof stored in the remaining battery energy level memory; and
a capacity and remaining energy level adder configured to calculate a total battery capacity being a sum of a capacity of the battery in service and capacities of the batteries out of service, and calculate a total remaining battery energy level being a sum of a remaining energy level of the battery in service and remaining energy levels of the batteries out of service, wherein
the display controller is configured to implement a control to have a time display graphic comprising a total time display portion representative of an operable time for the electronic device to be operable with the total battery capacity, and a total remaining time display portion representative of an operable time for the electronic device to be operable with the total remaining battery energy level, displayed on the screen display.

82. The electronic device according to claim 81, wherein the total remaining time display portion comprises a combination of a remaining time display part representative of the first set of information on operable time and a remaining time display part representative of the second set of information on operable time.

83. The electronic device according to claim 82, wherein the display controller is configured to implement a control to display the remaining time display part representative of the first set of information on operable time and the remaining time display part representative of the second set of information on operable time, having dimensions thereof commensurate with associated remaining times.

84. A remaining battery energy level displaying method comprising:
reading a battery ID of a battery in service attached to an electronic device;
calculating a remaining energy level of the battery in service;
having remaining energy levels of batteries subjected to selective attachment to the electronic device, respectively associated with battery IDs thereof, stored in a remaining battery energy level memory;
working for a new battery not stored in the remaining battery energy level memory, attached to the electronic device, to display on a screen display a message prompting a selection by user to or not to store a remaining energy level of the new battery in the remaining battery energy level memory;
working for an instruction signal input for storage of remaining energy level of the new battery, to have a calculated remaining energy level of the new battery, associated with an ID of the new battery, stored in the remaining battery energy level memory; and
displaying on the screen display a first set of information on remaining energy level representative of the remaining energy level of the battery in service, and a second set of information on remaining energy level representative of remaining energy levels of batteries out of service else than the battery in service having remaining energy levels thereof stored in the remaining battery energy level memory.

85. An operable time displaying method comprising:
reading a battery ID of a battery in service attached to an electronic device;
calculating a remaining energy level of the battery in service;
having remaining energy levels of batteries subjected to selective attachment to the electronic device, respectively associated with battery IDs thereof, stored in a remaining battery energy level memory;
working for a new battery not stored in the remaining battery energy level memory, attached to the electronic device, to display on a screen display a message prompting a selection by user to or not to store a remaining energy level of the new battery in the remaining battery energy level memory;
working for an instruction signal input for storage of remaining energy level of the new battery, to have a calculated remaining energy level of the new battery, associated with an ID of the new battery, stored in the remaining battery energy level memory;
working on bases of respective remaining energy levels of the batteries stored in the remaining battery energy level memory, to calculate operable times for the electronic device to be operable by the batteries, respectively; and
displaying on the screen display a first set of information on operable time representative of an operable time by the battery in service, and a second set of information on operable time representative of operable times by batteries out of service else than the battery in service having remaining energy levels thereof stored in the remaining battery energy level memory.

86. The remaining battery energy level displaying method according to claim 84, comprising:
reading a capacity of a battery from a battery capacity memory configured to store therein capacities of batteries of types applicable to the electronic device, associated with information on type of battery; and
using the capacity of the battery read from the battery capacity memory, to calculate a remaining energy level of the battery.

87. The operable time displaying method according to claim 85, comprising:
reading a capacity of a battery from a battery capacity memory configured to store therein capacities of batteries of types applicable to the electronic device, associated with information on type of battery; and
using the capacity of the battery read from the battery capacity memory, to calculate an operable time by the battery.

88. The remaining battery energy level displaying method according to claim 84, comprising having remaining energy level storage times of storage of respective remaining energy levels of the batteries, associated with battery IDs of the batteries, stored in the remaining battery energy level memory.

89. The operable time displaying method according to claim 85, comprising having remaining energy level storage times of storage of respective remaining energy levels of the batteries, associated with battery IDs of the batteries, stored in the remaining battery energy level memory.

90. The remaining battery energy level displaying method according to claim 88, comprising calculating a remaining energy level of the battery in service at a respective prescribed time, updating a remaining energy level of the battery in service stored in the remaining battery energy level memory to the remaining energy level calculated, and changing a remaining energy level storage time of the battery in service stored in the remaining battery energy level memory to a time of update of the remaining energy level.

91. The operable time displaying method according to claim 89, comprising calculating a remaining energy level of the battery in service at a respective prescribed time, updating a remaining energy level of the battery in service stored in the remaining battery energy level memory to the remaining energy level calculated, and changing a remaining energy level storage time of the battery in service stored in the remaining battery energy level memory to a time of update of the remaining energy level.

92. The remaining battery energy level displaying method according to claim 88, comprising:
reading an own power consumption from an own power consumption memory configured to have own power consumptions per unit time of batteries of types applicable to the electronic device, associated with information on type of battery, stored therein; and
calculating a remaining energy level correction value based on the own power consumption per unit time and a difference between a current time and a remaining energy level storage time stored in the remaining battery energy level memory, using the remaining energy level correction value to correct a remaining energy level of battery stored in the remaining battery energy level memory.

93. The operable time displaying method according to claim 89, comprising:
reading an own power consumption from an own power consumption memory configured to have own power consumptions per unit time of batteries of types applicable to the electronic device, associated with information on type of battery, stored therein; and
calculating a remaining energy level correction value based on the own power consumption per unit time and a difference between a current time and a remaining energy level storage time stored in the remaining battery energy level memory, using the remaining energy level correction value to correct a remaining energy level of battery stored in the remaining battery energy level memory.

94. The remaining battery energy level displaying method according to claim 84, comprising working for an instruction signal input for deletion of remaining energy level of a single battery selected from batteries having remaining energy levels thereof stored in the remaining battery energy level memory, to have a remaining energy level and a battery ID of a battery instructed by the instruction signal, deleted from the remaining battery energy level memory.

95. The operable time displaying method according to claim 85, comprising working for an instruction signal input for deletion of remaining energy level of a single battery selected from batteries having remaining energy levels thereof stored in the remaining battery energy level memory, to have a remaining energy level and a battery ID of a battery instructed by the instruction signal, deleted from the remaining battery energy level memory.

96. The remaining battery energy level displaying method according to claim 84, comprising having the first set of information on remaining energy level comprising a first display graphic representative of a remaining energy level of the battery in service, and the second set of information on remaining energy level comprising a second display graphic representative of remaining energy levels of the batteries out of service, individually displayed on the screen display.

97. The remaining battery energy level displaying method according to claim 96, comprising displaying, on the screen display, battery IDs of respective batteries corresponding to the first and the second display graphic.

98. The remaining battery energy level displaying method according to claim 96, comprising implementing a control to display:
the first display graphic comprising a capacity display part representative of a capacity of the battery in service, and a remaining energy level display part representative of a remaining energy level of the battery in service;
the second display graphic comprising a capacity display part representative of a capacity of a battery out of service, and a remaining energy level display part representative of a remaining energy level of the battery out of service; and
the capacity display parts and the remaining energy level display parts of the first and the second display graphic having dimensions thereof commensurate with associated capacities or remaining energy levels.

99. The remaining battery energy level displaying method according to claim 98, comprising corresponding to the first or the second display graphic, to have a ratio of the remaining energy level display part to the capacity display part, displayed on the screen display.

100. The operable time displaying method according to claim 85, comprising having the first set of information on operable time comprising a first numeral character sequence inclusive of numeral and character representative of an operable time by the battery in service, and the second set of information on operable time comprising a second numeral character sequence inclusive of numeral and character representative of operable times by the batteries out of service, individually displayed on the screen display.

101. The operable time displaying method according to claim 100, comprising displaying, on the screen display, battery IDs of respective batteries corresponding to the first and the second numeral character sequence.

102. The operable time displaying method according to claim 85, comprising having the first set of information on operable time comprising a first display graphic representative of an operable time by the battery in service, and the second set of information on operable time comprising a second display graphic representative of operable times by the batteries out of service, individually displayed on the screen display.

103. The operable time displaying method according to claim 102, comprising displaying, on the screen display, battery IDs of respective batteries corresponding to the first and the second display graphic.

104. The operable time displaying method according to claim 102, comprising displaying:
the first display graphic comprising a first display part representative of an operable time based on a capacity of the battery in service, and a second display part representative of an operable time based on a remaining energy level of the battery in service;
the second display graphic comprising a first display part representative of an operable time based on a capacity of a battery out of service, and a second display part representative of an operable time based on a remaining energy level of the battery out of service; and
the first display parts and the second display parts of the first and the second display graphic having dimensions thereof commensurate with associated operable times.

105. The operable time displaying method according to claim 104, comprising corresponding to the first or the second display graphic, to have a ratio of the second display part to the first display part, displayed on the screen display.

106. A remaining battery energy level displaying method comprising:
reading a battery ID of a battery in service attached to an electronic device;
calculating a remaining energy level of the battery in service;
having remaining energy levels of batteries subjected to selective attachment to the electronic device, respectively associated with battery IDs thereof, stored in a remaining battery energy level memory;
calculating a total battery capacity being a sum of a capacity of the battery in service and capacities of batteries out of service else than the battery in service having remaining energy levels thereof stored in the remaining battery energy level memory, calculating a total remaining battery energy level being a sum of a remaining energy level of the battery in service and remaining energy levels of the batteries out of service;
displaying on a screen display a first set of information on remaining energy level representative of a remaining energy level of the battery in service, and a second set of information on remaining energy level representative of remaining energy levels of the batteries out of service; and
having a total capacity and remaining energy level display graphic comprising a total capacity display portion representative of the total battery capacity, and a total remaining energy level display portion representative of the total remaining battery energy level, displayed on the screen display.

107. The remaining battery energy level displaying method according to claim 106, comprising having the total remaining energy level display portion of the total capacity and remaining energy level display graphic as a combination of a remaining energy level display part representative of the first set of information on remaining energy level and a remaining energy level display part representative of the second set of information on remaining energy level.

108. The remaining battery energy level displaying method according to claim 106, comprising displaying the remaining energy level display part representative of the first set of information on remaining energy level and the remaining energy level display part representative of the second set of information on remaining energy level, having dimensions thereof commensurate with associated remaining energy levels.

109. The remaining battery energy level displaying method according to claim 106, comprising having a ratio of the total remaining energy level display portion to the total capacity display portion, displayed on the screen display.

110. An operable time displaying method comprising:
reading a battery ID of a battery in service attached to an electronic device;
calculating a remaining energy level of the battery in service;
having remaining energy levels of batteries subjected to selective attachment to the electronic device, respectively associated with battery IDs thereof, stored in a remaining battery energy level memory;
working on bases of respective remaining energy levels of the batteries, to calculate operable times for the electronic device to be operable by the batteries, respectively;
calculating a total battery capacity being a sum of a capacity of the battery in service and capacities of batteries out of service else than the battery in service having remaining energy levels thereof stored in the remaining battery energy level memory, calculating a total remaining battery energy level being a sum of a remaining energy level of the battery in service and remaining energy levels of the batteries out of service;
displaying on a screen display a first set of information on operable time representative of an operable time by the battery in service, and a second set of information on operable time representative of operable times by the batteries out of service; and
having a numeral character sequence inclusive of numeral and character representative of an operable time for the electronic device to be operable with the total remaining battery energy level, displayed on the screen display.

111. An operable time displaying method comprising:
reading a battery ID of a battery in service attached to an electronic device;
calculating a remaining energy level of the battery in service;
having remaining energy levels of batteries subjected to selective attachment to the electronic device, respectively associated with battery IDs thereof, stored in a remaining battery energy level memory;
working on bases of respective remaining energy levels of the batteries, to calculate operable times for the electronic device to be operable by the batteries, respectively;
calculating a total battery capacity being a sum of a capacity of the battery in service and capacities of batteries out of service else than the battery in service having remaining energy levels thereof stored in the remaining battery energy level memory, calculating a total remaining battery energy level being a sum of a remaining energy level of the battery in service and remaining energy levels of the batteries out of service;
displaying on a screen display a first set of information on operable time representative of an operable time by the battery in service, and a second set of information on operable time representative of operable times by the batteries out of service; and
having a time display graphic comprising a total time display portion representative of an operable time for the electronic device to be operable with the total battery capacity, and a total remaining time display portion representative of an operable time for the electronic device to be operable with the total remaining battery energy level, displayed on the screen display.

112. The operable time displaying method according to claim 111, comprising having the total remaining time display portion as a combination of a remaining time display part representative of the first set of information on operable time and a remaining time display part representative of the second set of information on operable time.

113. The operable time displaying method according to claim 112, comprising implementing a control to display the remaining time display part representative of the first set of information on operable time and the remaining time display part representative of the second set of information on operable time, having dimensions thereof commensurate with associated remaining times.

114. The electronic device according to claim 60, further comprising
a battery capacity memory configured to store therein capacities of batteries of types applicable to the electronic device, associated with information on type of battery, wherein
the remaining battery energy level calculator is configured to use a capacity of battery stored in the battery capacity memory, to calculate a remaining energy level of battery.

115. The electronic device according to claim 60, wherein the remaining battery energy level memory is configured to store therein remaining energy level storage times of storage of respective remaining energy levels of the batteries, associated with battery IDs of the batteries.

116. The electronic device according to claim 115, further comprising a remaining energy level update controller configured to calculate a remaining energy level of the battery in service at a respective prescribed time, updating a remaining energy level of the battery in service stored in the remaining battery energy level memory to the remaining energy level calculated, and change a remaining energy level storage time of the battery in service stored in the remaining battery energy level memory to a time of update of the remaining energy level.

117. The electronic device according to claim 115, further comprising:
an own power consumption memory configured to have own power consumptions per unit time of batteries of types applicable to the electronic device, associated with information on type of battery, stored therein; and
a remaining battery energy level corrector configured to calculate a remaining energy level correction value based on an own power consumption per unit time and a difference between a current time and a remaining energy level storage time stored in the remaining battery energy level memory, and use the remaining energy level correction value to correct a remaining energy level of battery stored in the remaining battery energy level memory.

118. The electronic device claim 60, further comprising a remaining energy level deletion controller configured to work for an instruction signal input for deletion of remaining energy level of a single battery selected from batteries having remaining energy levels thereof stored in the remaining battery energy level memory, to have a remaining energy level and a battery ID of a battery instructed by the instruction signal, deleted from the remaining battery energy level memory.
